(19) United States
(12) Patent Application Publication
(10) Pub. No.: US 2025/0338496 A1
(43) Pub. Date: Oct. 30, 2025

(54) SEMICONDUCTOR DEVICE, FABRICATION METHOD THEREOF AND MEMORY SYSTEM

(71) Applicant: YANGTZE MEMORY TECHNOLOGIES CO., LTD., Wuhan (CN)

(72) Inventors: Yuhui Han, Wuhan (CN); Yang Chen, Wuhan (CN); Kun Zhang, Wuhan (CN)

(21) Appl. No.: 18/821,717

(22) Filed: Aug. 30, 2024

(30) Foreign Application Priority Data
Apr. 29, 2024 (CN) 202410533640.2

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

According to one aspect of the present disclosure, a semiconductor device is provided. The semiconductor device may include a stack structure including a plurality of gate layers stacked along a first direction. The semiconductor device may include a plurality of contacts connected with the gate layers located at different stacking heights, respectively. The gate layer may extend from a first region to a second region of the stack structure along a second direction, a portion of the gate layer located in the second region may include two sub-gate layers disposed opposite each other along a third direction, and the first direction, the second direction, and the third direction may intersect. The sub-gate layer may include an extension along the second direction and a protrusion connected with the extension. The contact may extend along the first direction and may be connected with the extension and the protrusion of the gate layer.

### CROSS-REFERENCE TO RELATED APPLICATIONS

This application claims the benefit of priority to Chinese Application No. 202410533640.2, filed on Apr. 29, 2024, which is incorporated herein by reference in its entirety.

### TECHNICAL FIELD

The present disclosure relates to the field of semiconductor design and manufacture, and particularly to a structure of a semiconductor device, a fabrication method of a semiconductor device and a memory system.

### BACKGROUND

Taking three-dimensional memory as an example, some semiconductor devices include stack structures. The stack structure includes a plurality of stacked gate layers. As the number of stacked layers in the stack structure increases constantly, etch depths of contact holes required by contacts (CT) extending to different gate layers becomes increasingly large, imposing higher requirements on the CT etch processes and the processes for an etch stop layer. In order to reduce process difficulties and simplify process operations, a Self-align Contact (SCT) architecture is proposed. The SCT process may cause the contact hole to stop at each gate layer accurately using a Stair Step (SS) cut process, so as to achieve the combination of the SS process and the CT process.

It is to be understood that the content described in the “background portion” is intended only to assist in understanding the technical solution disclosed by the present disclosure, and does not necessarily belong to the existing technology prior to the filing date of the present disclosure.

### SUMMARY

According to one aspect of the present disclosure, a semiconductor device is provided. The semiconductor device may include a stack structure including a plurality of gate layers stacked along a first direction. The semiconductor device may include a plurality of contacts connected with the gate layers located at different stacking heights, respectively. The gate layer may extend from a first region of the stack structure to a second region of the stack structure along a second direction, a portion of the gate layer located in the second region may include two sub-gate layers disposed opposite to each other along a third direction, and the first direction, the second direction, and the third direction may intersect each other. The sub-gate layer may include an extension extending along the second direction and a protrusion connected with the extension, with the protrusion of one of the sub-gate layers protruding toward the other sub-gate layer opposite thereto. The contact may extend along the first direction and may be connected with the extension and the protrusion of the gate layer.

In some implementations, the protrusion may be disposed opposite to the contact in the third direction. In some implementations, the contact may be connected with the extension of the one of the sub-gate layers and connected with the protrusion of the other sub-gate layer.

In some implementations, the extension and the protrusion of a same sub-gate layer may be disposed around the contact. In some implementations, the contact may be connected with the extension and the protrusion of the same sub-gate layer.

In some implementations, the protrusion of the one of the sub-gate layers may be disposed as being staggered from the protrusion of the other sub-gate layer in the second direction.

In some implementations, the contact may be disposed as being staggered from the protrusion in the second direction.

In some implementations, the contact may be connected with at least one surface of the protrusion.

In some implementations, in a plane intersecting the first direction, a width of the extension may be greater than or equal to a width of the protrusion.

In some implementations, the semiconductor device may include a gate line slit structure. In some implementations, the gate line slit structure may extend along the first direction and may be connected with the plurality of gate layers stacked along the first direction.

In some implementations, the gate line slit structure may extend from the first region to the second region along the second direction, and a portion of the gate line slit structure located in the second region may include a first portion and a second portion. In some implementations, the first portion may extend along the second direction. In some implementations, the second portion may extend along a direction intersecting the second direction.

In some implementations, the gate line slit structure may include a first gate line slit structure, a second gate line slit structure, and a third gate line slit structure located between the first gate line slit structure and the second gate line slit structure. In some implementations, the third gate line slit structure may extend along a direction intersecting the second direction.

In some implementations, the extension may be located between the first portion and the second portion.

In some implementations, the gate line slit structure may include a first gate line slit structure and a second gate line slit structure adjacent to each other in the third direction. In some implementations, the second portion of the first gate line slit structure may extend toward the second gate line slit structure. In some implementations, the second portion of the second gate line slit structure may extend toward the first gate line slit structure. In some implementations, the second portion of the first gate line slit structure and the second portion of the second gate line slit structure may be connected with each other.

In some implementations, the gate line slit structure may include a first gate line slit structure and a second gate line slit structure adjacent to each other in the third direction. In some implementations, the second portion of the first gate line slit structure may extend toward the second gate line slit structure. In some implementations, the second portion of the second gate line slit structure may extend toward the first gate line slit structure. In some implementations, the second portion of the first gate line slit structure and the second portion of the second gate line slit structure may be disposed as being staggered from each other in the second direction.

In some implementations, at least one surface of the gate line slit structure may be a curved surface, and the curved surface may include at least one of a concave surface and a convex surface.

In some implementations, the gate line slit structure may extend in a wavy shape in a direction intersecting the first direction.

In some implementations, the semiconductor device may include a first channel structure and a second channel structure. In some implementations, the first channel structure may be located in the first region and may extend through portions of the plurality of gate layers that are located in the first region along the first direction. In some implementations, the second channel structure may be located in the second region and may at least extend through portions of the gate layers that are located in the second region along the first direction.

In some implementations, a plurality of the second channel structures may be arranged at intervals in the protrusion along an extending direction of the protrusion.

In some implementations, the contact may include a first sub-portion and a second sub-portion connected with each other. In some implementations, the first sub-portion may extend along the first direction. In some implementations, the second sub-portion may connect the gate layer and the first sub-portion at a stacking height where the gate layer corresponding to the contact is located.

According to another aspect of the present disclosure, a method of fabricating a semiconductor device is provided. The method may include forming a stack structure and forming a gate line slit and a contact hole in the stack structure. The stack structure may include a plurality of gate sacrificial layers stacked along a first direction. The method may include removing a portion of the gate sacrificial layer via the gate line slit to form a sacrificial void. The method may include forming a gate layer in the sacrificial void and forming a contact in the contact hole. The gate layer may extend along a second direction and may include two sub-gate layers disposed opposite to each other along a third direction, and the first direction, the second direction, and the third direction may intersect each other. The sub-gate layer may include an extension extending along the second direction and a protrusion connected with the extension, and the protrusion of one of the sub-gate layers may protrude toward the other sub-gate layer opposite thereto. The contact may extend along the first direction and may be connected with the extension and the protrusion of the gate layer.

In some implementations, the stack structure may include a first region and a second region arranged along the second direction. In some implementations, forming the gate line slit may include forming first holes extending in the stack structure along the first direction. In some implementations, a plurality of the first holes may include a plurality of first region first holes located in the first region and a plurality of second region first holes located in the second region, a part of the plurality of second region first holes may be arranged at intervals along the second direction, and the other part of the plurality of second region first holes may be arranged at intervals along a direction intersecting the second direction. In some implementations, forming the gate line slit may include at least removing a portion of the stack structure that is located between adjacent ones of the first holes to form the gate line slit.

In some implementations, the method may include forming a first channel hole and a second channel hole. In some implementations, the first channel hole and the second channel hole both may extend in the stack structure along the first direction. In some implementations, the first channel hole and the second channel hole may be formed in a process of forming the first hole.

In some implementations, removing the portion of the gate sacrificial layer via the gate line slit to form the sacrificial void may include forming two sacrificial sub-voids disposed opposite to each other along the third direction. In some implementations, the sacrificial sub-void may include a first void extending along the second direction and a second void communicated with the first void, with the second void of one of the sacrificial sub-voids protruding toward the other sacrificial sub-void opposite thereto.

In some implementations, forming the sacrificial void may include forming the sacrificial void via the gate line slit and the contact hole. In some implementations, a width of the first void may be greater than or equal to a width of the second void in a plane intersecting the first direction.

According to a further aspect of the present disclosure, a memory system is provided. The memory system may include at least one semiconductor device. The at least one semiconductor device may include a stack structure including a plurality of gate layers stacked along a first direction. The at least one semiconductor device may include a plurality of contacts connected with the gate layers located at different stacking heights, respectively. The gate layer may extend from a first region of the stack structure to a second region of the stack structure along a second direction, a portion of the gate layer located in the second region may include two sub-gate layers disposed opposite to each other along a third direction, and the first direction, the second direction, and the third direction may intersect each other. The sub-gate layer may include an extension extending along the second direction and a protrusion connected with the extension, with the protrusion of one of the sub-gate layers protruding toward the other sub-gate layer opposite thereto. The contact may extend along the first direction and may be connected with the extension and the protrusion of the gate layer. The memory system may include a controller coupled with the semiconductor device and configured to control the semiconductor device to store data.

### BRIEF DESCRIPTION OF THE DRAWINGS

Other features, purposes and beneficial effects of the present disclosure will become more apparent by reading the detailed description of non-limitative implementations made by reference to the following figures. In the figures:

FIG. 1 is a local top view of a semiconductor device, according to an implementation of the present disclosure;

FIG. 2 is a local top view of a semiconductor device, according to another implementation of the present disclosure;

FIG. 3 is a local top view of a semiconductor device, according to still another implementation of the present disclosure;

FIG. 4 is a local top view of a first region of a stack structure, according to an implementation of the present disclosure;

FIG. 5 is a cross-sectional view of the first region shown in FIG. 4 taken along a line A-A′;

FIG. 6 is a local top view of a second region of a stack structure, according to an implementation of the present disclosure;

FIG. 7 is a cross-sectional view of the second region shown in FIG. 6 taken along a line B-B′;

FIG. 8 is a local top view of a semiconductor device, according to an implementation of the present disclosure;

FIG. 9 is a local top view of a semiconductor device, according to an implementation of the present disclosure;

FIG. 10 is a local top view of a semiconductor device, according to another implementation of the present disclosure;

FIG. 11 is a local top view of a semiconductor device, according to another implementation of the present disclosure;

FIG. 12 is a local top view of a semiconductor device, according to still another implementation of the present disclosure;

FIG. 13 is a local top view of a semiconductor device, according to still another implementation of the present disclosure;

FIG. 14 is a top view of a gate line slit structure, according to another implementation of the present disclosure;

FIG. 15 is a local top view of a second region of a stack structure, according to another implementation of the present disclosure;

FIG. 16 is a cross-sectional view of the second region shown in FIG. 15 taken along a line C-C′;

FIG. 17 is a local top view of a first region and a second region of a stack structure, according to an implementation of the present disclosure;

FIG. 18 is a local cross-sectional view of the first region and the second region of the stack structure, according to an implementation of the present disclosure;

FIG. 19 is a cross-sectional view of a first channel structure and a second channel structure, according to one implementation of the present disclosure;

FIG. 20 is a flow diagram of a method of fabricating a semiconductor device, according to one implementation of the present disclosure;

FIGS. 20-32 are respectively process diagrams of a method of fabricating a semiconductor device, according to an implementation of the present disclosure; and

FIG. 33 is a schematic structural diagram of a memory system, according to an implementation of the present disclosure.

### DETAILED DESCRIPTION

The present disclosure will be described in detail below in conjunction with the accompanying drawings, and the example implementations referred to herein are used for explaining the present disclosure only and are not intended to limit the scope of the present disclosure. Like reference numbers denote like elements throughout the specification.

For ease of illustration, the thicknesses, sizes and shapes of components have been slightly adjusted in the drawings. The drawings are merely examples and are not drawn to scale precisely. As used herein, terms “approximately” “about”, and similar terms are used to represent approximation, instead of representing a degree, and are intended to describe an inherent deviation in a measured value or a calculated value as recognized by those of ordinary skills in the art.

It is also to be understood that the expression “and/or” comprises any or all combinations of one or more of associated items listed. The expressions, such as “comprise”, “comprising”, “have”, “include”, and/or “including”, are open-ended expressions, rather than close-ended expressions. They represent that there exists the stated features, elements and/or components, but the existence or addition of one or more another features, elements, components and/or combinations thereof is not precluded. Moreover, the expression, such as “at least one of . . . ”, appearing before a list of listed features, modifies the whole list of features, rather than an individual element therein. In describing the implementations of the present disclosure, “may” is used to represent “one or more implementations of the present disclosure”. Moreover, the term “example” is intended to refer to an example or illustration.

In addition, expressions such as “connection”, “cover”, and/or “formed above . . . ” used in the present disclosure may represent direct contact or indirect contact between respective components, unless otherwise expressly defined or derived from the context.

Unless otherwise defined, all phrases (including technical terms and technological terms) as used herein have the same meanings as those generally understood by those of ordinary skills in the field to which the present disclosure pertains. Furthermore, unless otherwise stated expressly in the present disclosure, terms as defined in common dictionaries should be interpreted as having a meaning that is consistent with their meanings in the context of the related technologies, and should not be interpreted in an idealized or overly formal sense.

It is to be noted that implementations and features in the implementations of the present disclosure may be mutually combined in the case of no conflicts. Moreover, unless otherwise defined explicitly or conflicting with the context, specific operations included in a method as set forth in the present disclosure are not necessarily limited to an order as set forth, but may be carried out in any order or in parallel. The present disclosure will be detailed below by reference to the drawings and in conjunction with the implementations.

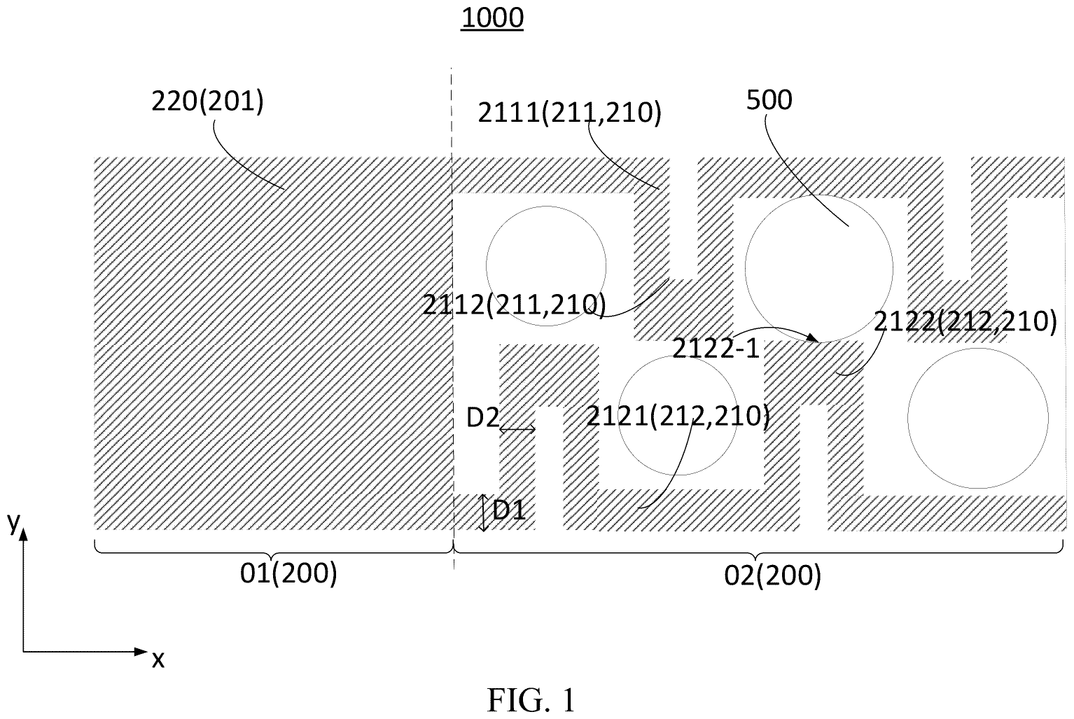

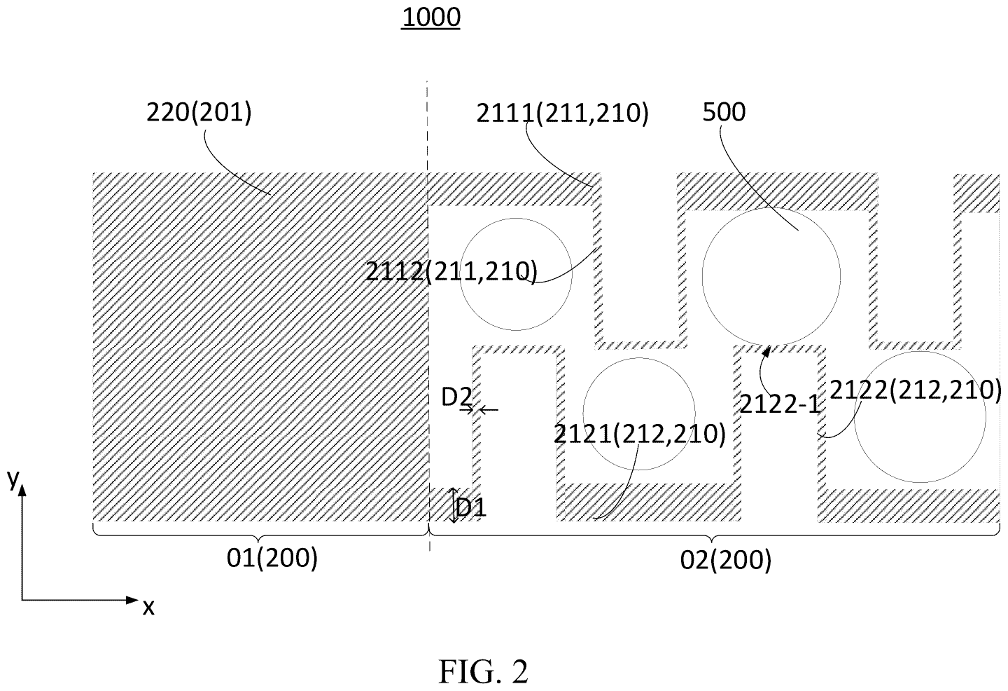

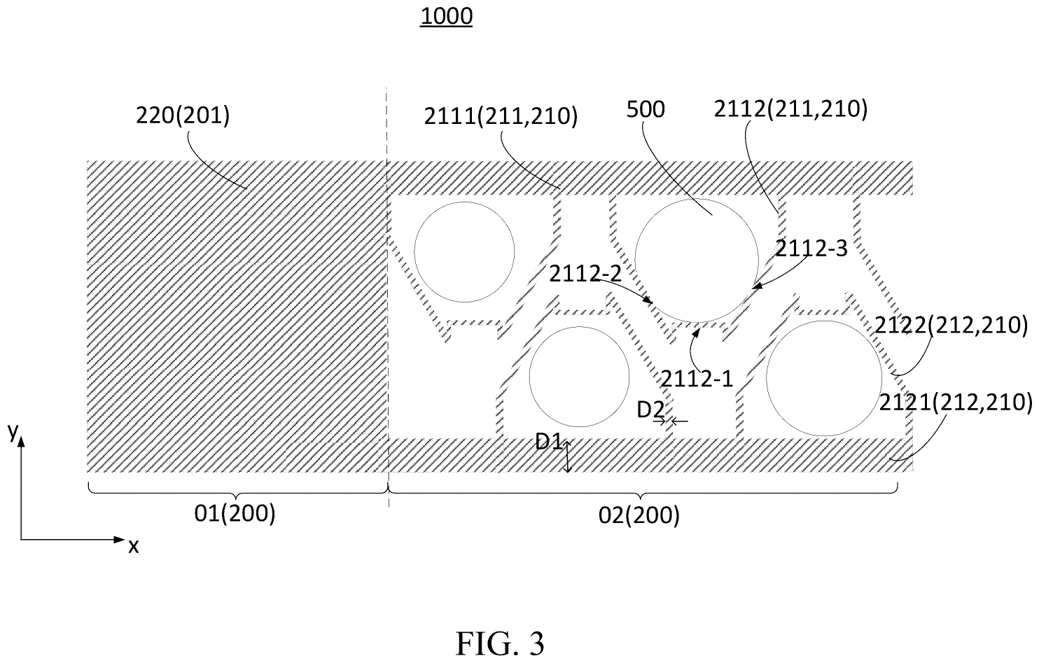

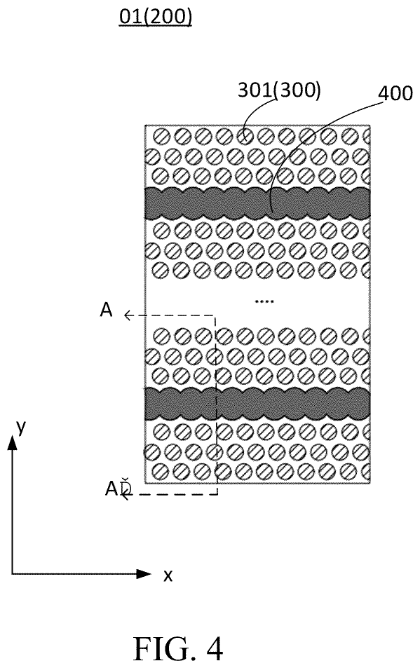

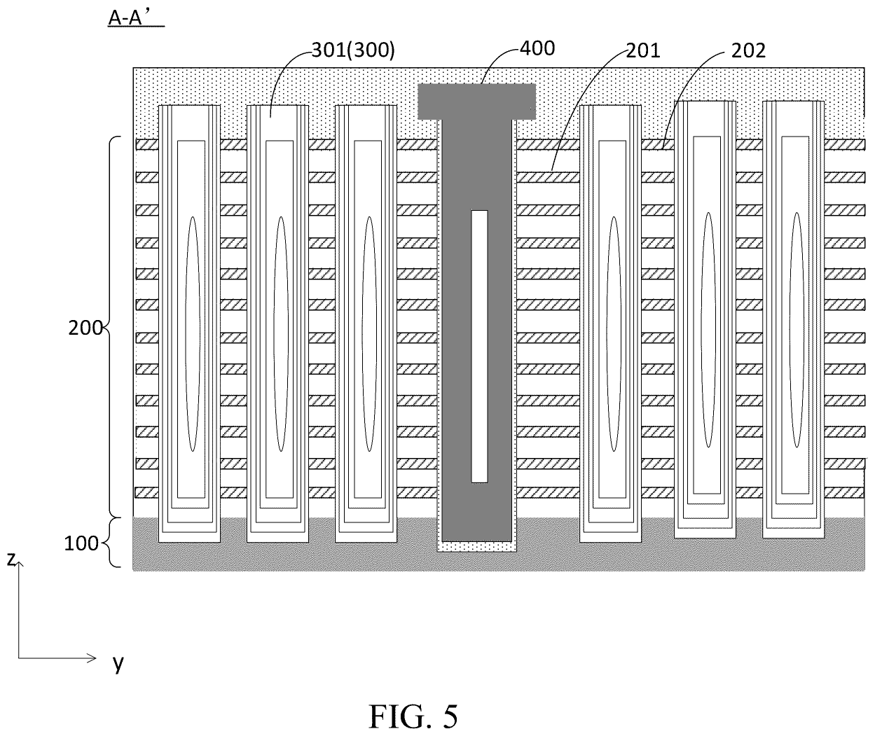

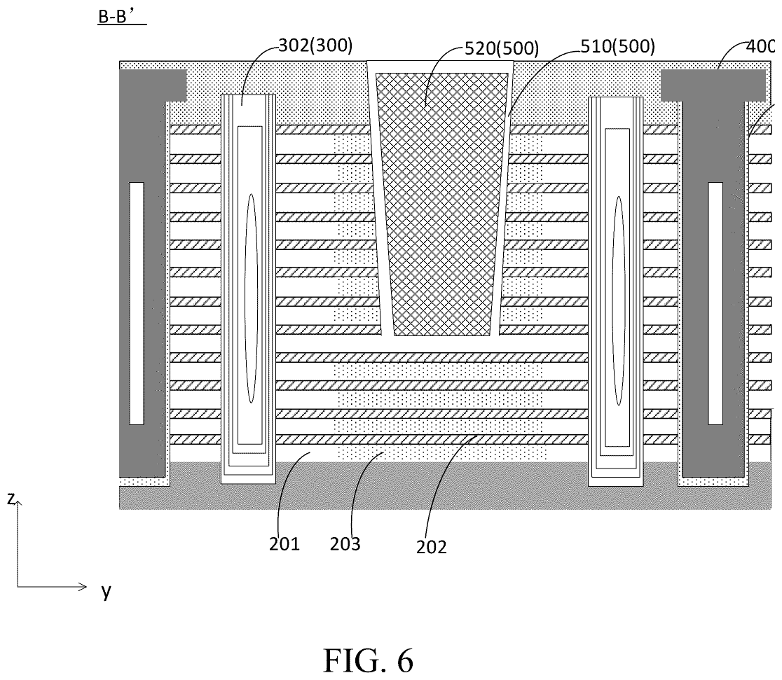

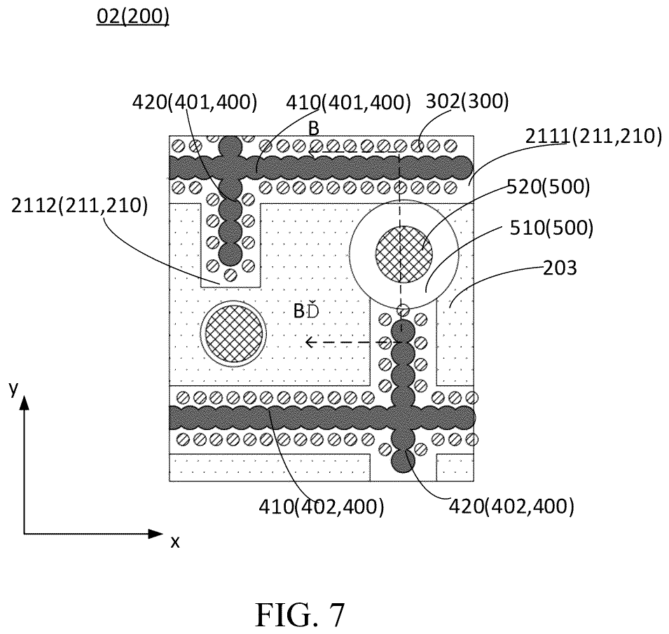

FIG. 1 is a local top view of a semiconductor device 1000, according to an implementation of the present disclosure. FIG. 2 is a local top view of the semiconductor device 1000, according to another implementation of the present disclosure. FIG. 3 is a local top view of the semiconductor device 1000, according to still another implementation of the present disclosure. FIG. 4 is a local top view of a first region 01 of a stack structure 200, according to an implementation of the present disclosure. FIG. 5 is a cross-sectional view of the first region 01 shown in FIG. 4 taken along a line A-A′. FIG. 6 is a local top view of a second region 02 of the stack structure 200, according to an implementation of the present disclosure. FIG. 7 is a cross-sectional view of the second region 02 shown in FIG. 6 taken along a line B-B′.

As shown in FIGS. 1-7, the semiconductor device 1000 may include a stack structure 200 and a plurality of contacts 500. The stack structure 200 includes a plurality of gate layers 201 stacked along a first direction (z-direction). The plurality of contacts 500 are respectively connected with a plurality of gate layers 201 located at different stacking heights. The gate layer 201 extends from a first region 01 of the stack structure 200 to a second region 02 of the stack structure 200 along a second direction (x-direction), a portion 210 of the gate layer 201 located in the second region 02 includes two sub-gate layers disposed opposite each other along a third direction (y-direction), e.g., a first sub-gate layer 211 and a second sub-gate layer 212, the x-direction, the y-direction, and the z-direction intersect each other. The sub-gate layer includes an extension extending along the x-direction and a protrusion connected with extension. For example, the first sub-gate layer 211 includes a first extension 2111 (hereinafter referred to as a first extension 2111) extending along the x-direction and a first protrusion 2112 (hereinafter referred to as a first protrusion 2112) connected with the first extension 2111; the second sub-gate layer 212 includes a second extension 2121 (hereinafter referred to as a second extension 2121) extending in the x-direction and a second protrusion 2122 (hereinafter referred to as a second protrusion 2122) connected with the second extension 2121. The protrusion of one of the sub-gate layers protrudes toward the other sub-gate layer opposite thereto. For example, the first protrusion 2112 protrudes toward the second sub-gate layer 212; the second protrusion 2122 protrudes toward the first sub-gate layer 211. The contact 500 extends along the z-direction and is connected with the extension and the protrusion of the same gate layer 201. For example, the contact 500 corresponding to the gate layer 201 may extend along the z-direction and be connected with the first extension 2111 and the second protrusion 2122 of the gate layer 201; or the contact 500 corresponding to the gate layer 201 may extend along the z-direction and be connected with the first extension 2111 and the first protrusion 2112 of the gate layer 201; or the contact 500 corresponding to the gate layer 201 may extend along the z-direction and be connected with the second extension 2121 and the second protrusion 2122 of the gate layer 201; or the contact 500 corresponding to the gate layer 201 may extend along the z-direction and be connected with the second extension 2121 and the first protrusion 2112 of the gate layer 201.

In the semiconductor device provided according to at least one implementation of the present disclosure, the contact extends along a first direction and may be connected with both the extension and the protrusion of the corresponding gate layer. In other words, the contact may be connected with a plurality of portions of the same gate layer, thereby reducing a contact resistance between the contact and the gate layer. Furthermore, the connection of the contact with the plurality of portions of the same gate layer may reduce an extending dimension of the gate layer, e.g., an extending dimension of the gate layer in the x-direction, while ensuring the electrical performance of the semiconductor device, thereby reducing a bulk resistance of the gate layer and improving the level of integration of the semiconductor device.

Specifically, with reference to FIGS. 4-7, the stack structure 200 may be disposed on a side of a substrate 100. The substrate 100 may include a semiconductor material layer, where the semiconductor material may include, but is not limited to, an elemental semiconductor material (e.g., silicon or germanium), a group III-V compound semiconductor material, a group II-VI compound semiconductor material, an organic semiconductor material or other semiconductor materials known in the art. In an example, the substrate 100 may include a silicon substrate. Additionally, the substrate 100 may be a composite structure, for example, the composite structure may include a layer structure connected with a channel structure 300. The channel structure 300 will be described in detail below in conjunction with the drawings.

The stack structure 200 includes a first region 01 and a second region 02 arranged adjacent to each other in the x-direction, where the first region 01 may include a second dielectric layer 202 and the gate layer 201 stacked alternately; and the second region 02 may include a first dielectric layer 203 and the second dielectric layer 202 stacked alternately.

The gate layer 201 may include a conductive material, such as any one of or any combination of tungsten (W), cobalt (Co), copper (Cu), aluminum (Al), doped crystalline silicon, or silicide. The second dielectric layer 202 may be used as an isolation stacking layer, including, but not limited to, an insulation dielectric material layer such as a silicon oxide layer. The first dielectric layer 203 and the second dielectric layer 202 are two different insulation dielectric material layers, for example, the first dielectric layer 203 may include, but is not limited to, an insulation dielectric material layer such as a silicon nitride layer. Furthermore, a plurality of first dielectric layers 203 and the plurality of gate layers 201 may have the same stacking height. In addition, the number of layers of the stack structure 200 is not limited to the number of layers shown in the figure, but may be set otherwise as desired, such as 32 layers, 64 layers, or 128 layers.

In other words, the stack structure 200 may include the second dielectric layer 202 and a composite layer stacked alternately, where the composite layer includes the gate layer 201 and the first dielectric layer 203 disposed at the same layer. For example, the gate layer 201 and the first dielectric layer 203 may be arranged as being connected with each other in an x-y plane intersecting the z-direction, the gate layer 201 extends from the first region 01 of the stack structure 200 to the second region 02 along the x-direction and is connected with the first dielectric layer 203 disposed at the same layer, and the first dielectric layer 203 is located in the second region 02.

The contact 500 extends in the second region 02 of the stack structure 200 along the z-direction, and the gate layer 201 extends from the first region 01 into the second region 02 along the x-direction. The portion 210 of the gate layer 201 that is located in the second region 02 includes a plurality of extensions and a plurality of protrusions, and the contact 500 is connected with the plurality of extensions and the plurality of protrusions of the same gate layer 201.

Taking a three-dimensional memory as an example, the semiconductor device may include the stack structure formed by stacking the gate layers and the second dielectric layers alternately, where a word line contact located in a stair step region of the stack structure may achieve an electrical connection of the gate layer with an external circuit. However, as the number of stacking layers increases, forming the word line contact in the stair step region requires a plurality of processes, such as lithography and etching, so as to form a stair topography having stair steps, thereby greatly increasing manufacturing costs of the semiconductor device. Furthermore, as the number of stair steps increases, the area of the stair step required to be formed becomes increasingly large, restricting an increase in the level of integration of the semiconductor device. In addition, as the number of stacking layers increases, the degree of warpage of a wafer rises, making alignment of the word line contact with a stair step surface in the stair step region more difficult, thus leading to deterioration of the reliability of the semiconductor device or a low yield of an electrical test, which ultimately affects the reliability and overall performance of the semiconductor device.

The semiconductor device provided in the implementation of the present disclosure may achieve electrical connections of the gate layers located at different stacking heights with the external circuit by means of the plurality of contacts disposed in the second region of the stack structure, without forming a stair step therein and word line contacts on the stair step. Therefore, the fabrication process of the semiconductor device is simplified, the fabrication costs are reduced, and at the same time, a unit storage density, the reliability, and the overall performance of the semiconductor device may be improved.

In addition, the contact extends along a stacking direction and is connected with both the extension and the protrusion of the corresponding gate layer. In other words, the contact may be connected with a plurality of portions of the same gate layer, thereby reducing a contact resistance between the contact and the gate layer. Furthermore, the connection of the contact with the plurality of portions of the same gate layer may reduce an extending dimension of the gate layer while ensuring the electrical performance of the semiconductor device, thereby reducing a bulk resistance of the gate layer and improving the level of integration of the semiconductor device.

As shown in FIGS. 1-2, in some implementations of the present disclosure, the protrusion is disposed opposite to the contact 500 in the y-direction, the contact 500 is connected with the extension of a sub-gate layer and connected with the protrusion of the other sub-gate layer. For example, the first protrusion 2112 and the second protrusion 2122 are both disposed opposite to the contact 500 in the y-direction. The contact 500 corresponding to the gate layer 201 may extend along the z-direction and be connected with the first extension 2111 of the first sub-gate layer 211 and the second protrusion 2122 of the second sub-gate layer 212. Specifically, the second protrusion 2122 may include a portion 2122-1 (hereinafter referred to as a contacting portion 2122-1) that contacts the contact 500, and accordingly, the contact 500 may be connected with at least two surfaces of the gate layer 201, which surfaces include a surface of the first extension 2111 and a surface of the contacting portion 2122-1 of the second protrusion 2122.

Alternatively, the contact 500 corresponding to the gate layer 201 may extend along the z-direction and be connected with the second extension 2121 of the second sub-gate layer 212 and the first protrusion 2112 of the first sub-gate layer 211. In this case, the contact 500 may be also connected with at least two surfaces of the gate layer 201.

As shown in FIG. 3, in some implementations of the present disclosure, the extension and the protrusion of a same sub-gate layer may be disposed around the contact 500, and the contact 500 is connected with the extension and the protrusion of the same sub-gate layer. For example, the first extension 2111 and the first protrusion 2112 of the first sub-gate layer 211 may be disposed around the contact 500. The first protrusion 2112 may include a first portion 2112-1, a second portion 2112-2 and a third portion 2112-3, where the first portion 2112-1, the second portion 2112-2, and the third portion 2112-3 are connected with each other and disposed, together with the first extension 2111, around the contact 500, so that the contact 500 may be connected with at least four surfaces of the gate layer 201. Similarly, the second extension 2121 and the second protrusion 2122 of the second sub-gate layer 212 may be disposed around the contact 500, so that the contact 500 may be connected with at least four surfaces of the gate layer 201.

As shown in FIGS. 1-3, in some implementations of the present disclosure, the contact 500 is connected with at least one surface of the protrusion. For example, the contact 500 may be connected with a surface of the contacting portion 2122-1 of the second protrusion 2122 shown in FIG. 1 or FIG. 2; or the contact 500 may be connected with a surface of each of the first portion 2112-1, the second portion 2112-2, and the third portion 2112-3 included in the first protrusion 2112 shown in FIG. 3.

In addition, the protrusion of a sub-gate layer may be disposed as being staggered from the protrusion of the other sub-gate layer in the x-direction. For example, the first protrusion 2112 of the first sub-gate layer 211 is disposed as being staggered from the second protrusion 2122 of the second sub-gate layer 212 in the x-direction.

As an option, the contact 500 is disposed as being staggered from the protrusion in the x-direction. For example, the contact 500 may be disposed as being staggered from both the first protrusion 2112 and the second protrusion 2122 in the x-direction.

Accordingly, by optimizing a layout of the plurality of protrusions of the sub-gate layers, in the case of ensuring the connection of the contact with the plurality of portions of a same gate layer, the extending dimension of the gate layer may be reduced, thereby reducing the bulk resistance of the gate layer and improving the level of integration of the semiconductor device.

As shown in FIG. 1, in the plane (e.g., x-y plane) intersecting the z-direction, a width of the extension may be equal to a width of the protrusion. For example, in the x-y plane, a width D1 of the second extension 2121 is equal to a width D2 of the second protrusion 2122, where the width may be understood as a dimension of the extension or the protrusion in a direction perpendicular to a respective extending direction thereof.

As shown in FIG. 2 and FIG. 3, in the plane (e.g., x-y plane) intersecting the z-direction, the width of the extension may be greater than the width of the protrusion. For example, in the x-y plane, the width D1 of the second extension 2121 is greater than the width D2 of the second protrusion 2122, where the width may be understood as a dimension of the extension or the protrusion in a direction perpendicular to a respective extending direction thereof.

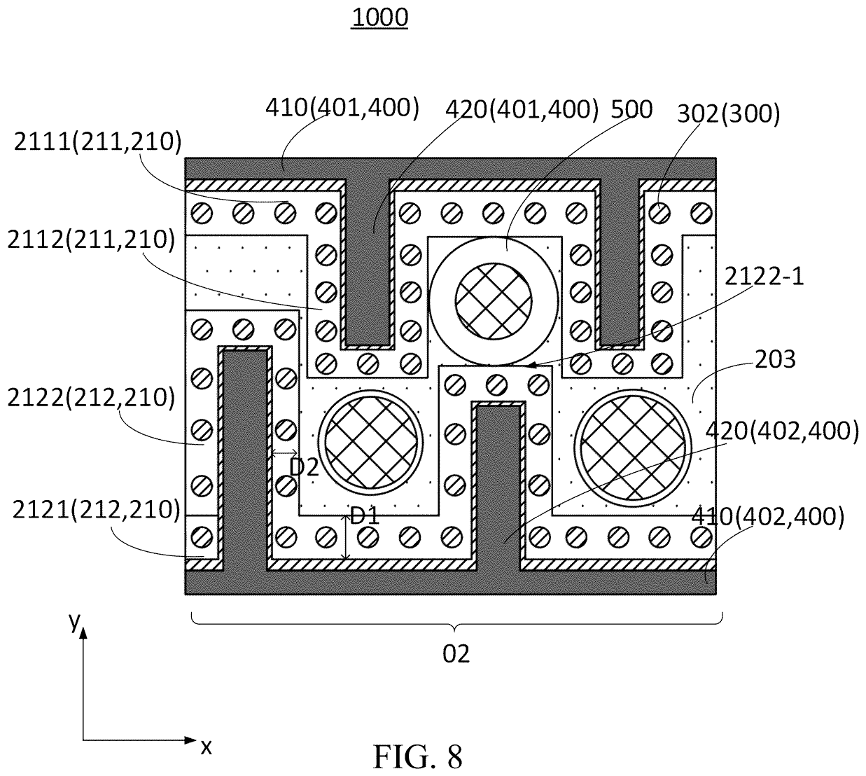

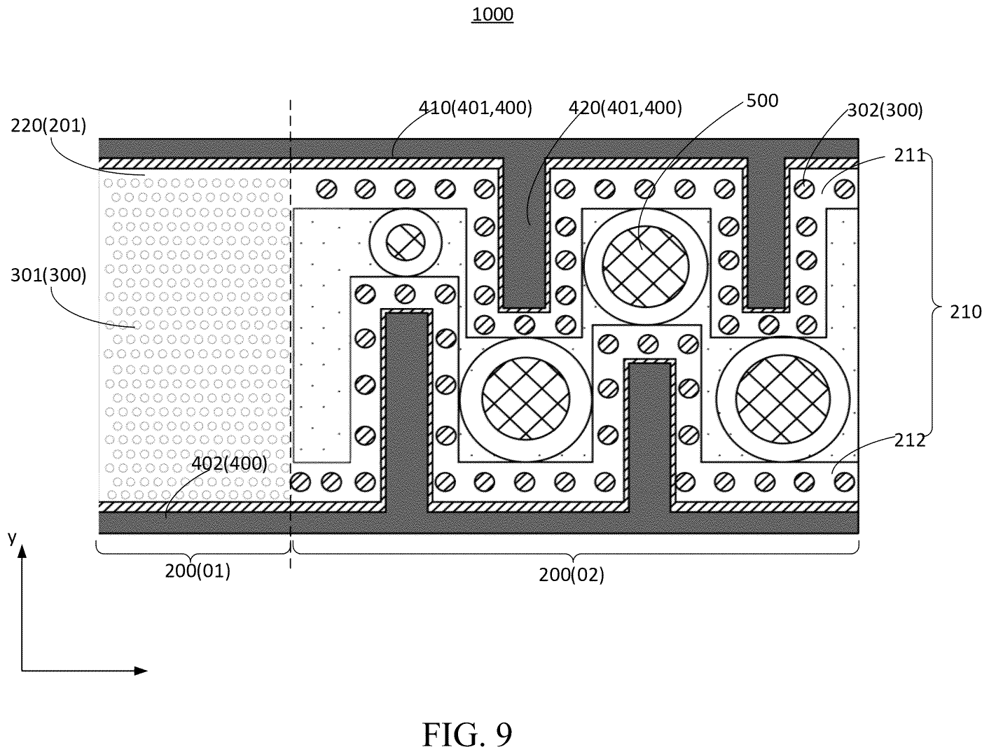

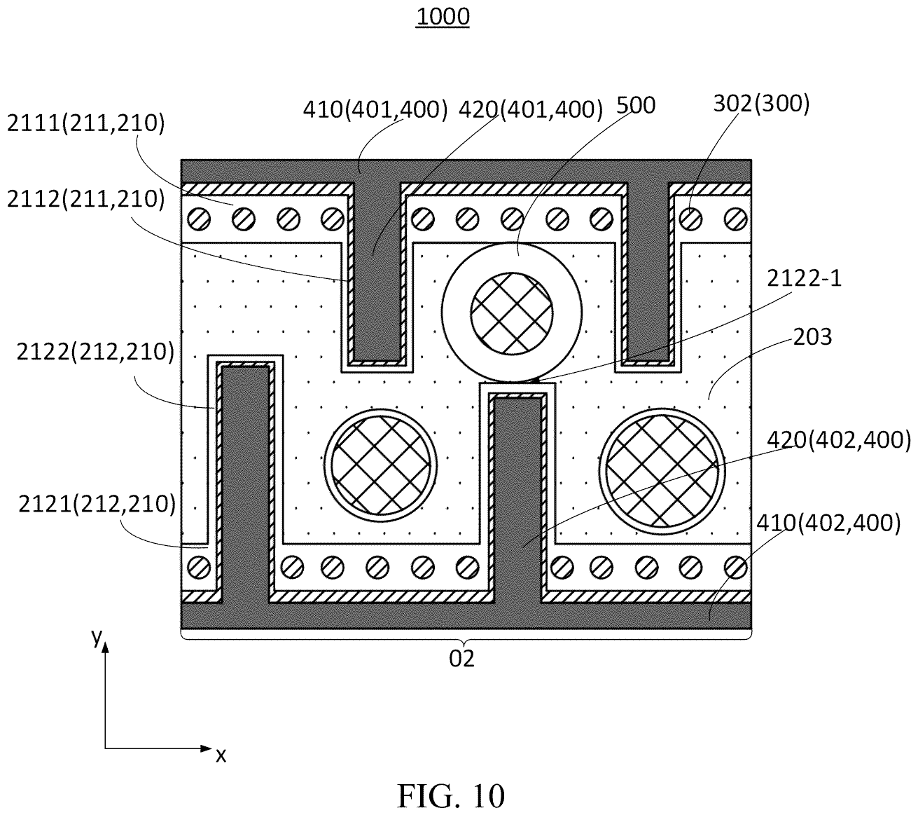

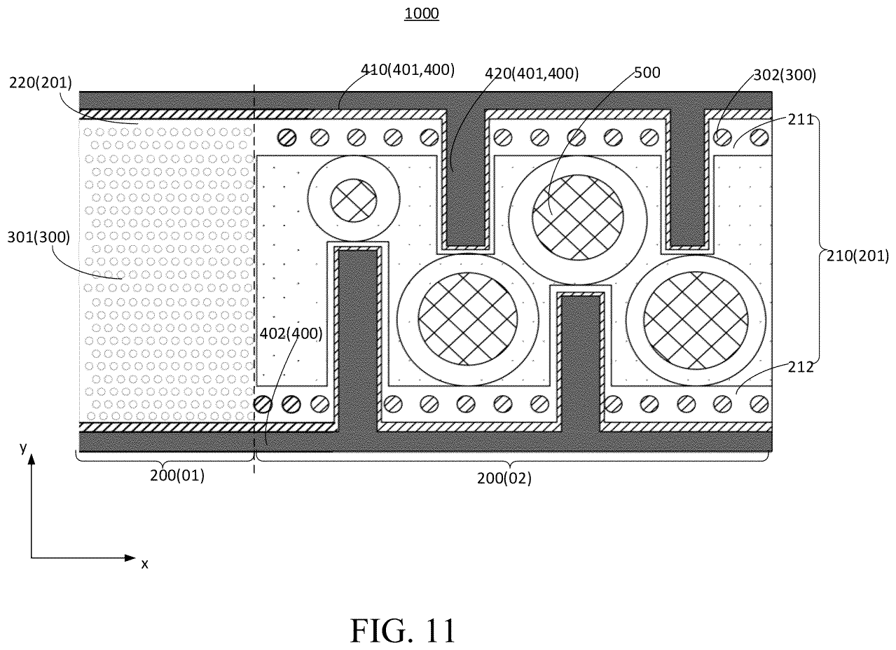

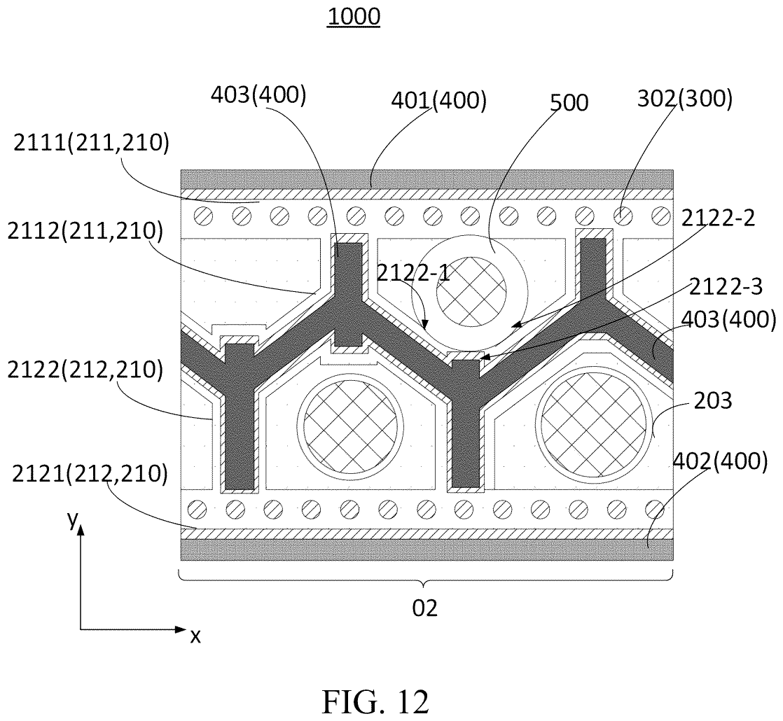

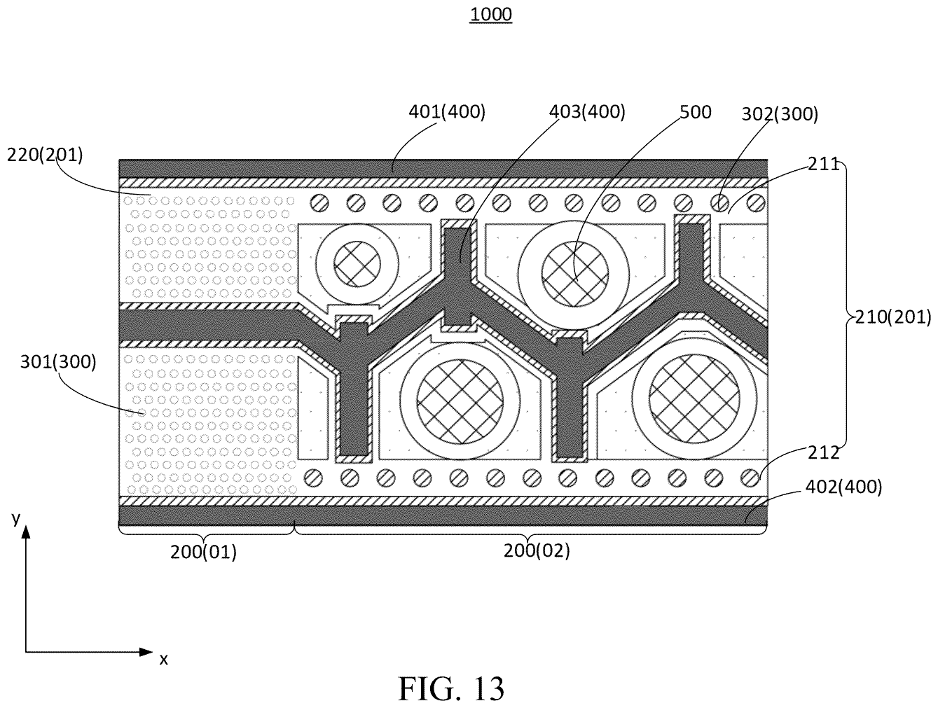

FIG. 8 is a local top view of the semiconductor device 1000, according to an implementation of the present disclosure. FIG. 9 is a local top view of the semiconductor device 1000, according to an implementation of the present disclosure. FIG. 10 is a local top view of the semiconductor device 1000, according to another implementation of the present disclosure. FIG. 11 is a local top view of the semiconductor device 1000, according to another implementation of the present disclosure. FIG. 12 is a local top view of the semiconductor device 1000, according to still another implementation of the present disclosure. FIG. 13 is a local top view of the semiconductor device 1000, according to still another implementation of the present disclosure.

With reference to FIGS. 5 and 7-13, the semiconductor device 1000 further includes a gate line slit structure 400, where the gate line slit structure 400 extends along the z-direction and is connected with the plurality of gate layers 201 stacked along the z-direction.

It is to be noted that a plurality of structures in the semiconductor device 1000 are omitted in FIGS. 1-3, such as the gate line slit structure 400, and the first channel structure 301, in order to facilitate observation of a shape of the gate layer 201 and a connection situation between the contact 500 and the corresponding gate layer 201. In addition, for ease of observation, filling patterns of the gate layer 201 and the contact 500 shown in FIGS. 1-3 are different from filling patterns of the gate layer 201 and the contact 500 shown in the subsequent figures.

As shown in FIGS. 8-11, in some implementations of the present disclosure, the gate line slit structure 400 extends from the first region 01 to the second region 02 along the x-direction. Furthermore, the gate line slit structure 400 may include a first gate line slit structure 401 and a second gate line slit structure 402, where the first gate line slit structure 401 and the second gate line slit structure 402 both may extend from the first region 01 to the second region 02 along the x-direction. In addition, the first gate line slit structure 401 and the second gate line slit structure 402 may be arranged adjacent to each other in the y-direction.

In an implementation, a portion of the gate line slit structure 400 that is located in the second region 02 may include a first portion 410 and a second portion 420, where the first portion 410 extends along the x-direction and the second portion 420 extends along a direction intersecting the x-direction. For example, the second portion 420 may extend along the y-direction, or the second portion 420 may extend along a direction that is different from each of the x-direction, the y-direction, and the z-direction.

In an implementation, a portion of the first gate line slit structure 401 located in the second region 02 may include the first portion 410 and the second portion 420, where the first portion 410 extends along the x-direction, and the second portion 420 extends along the y-direction. A portion of the second gate line slit structure 402 located in the second region 02 may also include a first portion 410 and a second portion 420, where the first portion 410 extends along the x-direction, and the second portion 420 extends along the y-direction.

Moreover, the second portion 420 of the first gate line slit structure 401 extends toward the second gate line slit structure 402, and the second portion 420 of the second gate line slit structure 402 extends toward the first gate line slit structure 401.

In an implementation, the first portion 410 and the second portion 420 may be connected with each other. For example, the first portion 410 and the second portion 420 of the first gate line slit structure 401 may be connected with each other; the first portion 410 and the second portion 420 of the second gate line slit structure 402 may also be connected with each other.

In an implementation, the first portion 410 and the second portion 420 may also be arranged at intervals. In this implementation, the extension may be located between the first portion 410 and the second portion 420. For example, the first extension 2111 may be located between the first portion 410 and the second portion 420 of the first gate line slit structure 401, and the second extension 2121 may be located between the first portion 410 and the second portion 420 of the second gate line slit structure 402.

In an implementation, the second portion 420 of the first gate line slit structure 401 and the second portion 420 of the second gate line slit structure 402 may be connected with each other. In an implementation, the second portion 420 of the first gate line slit structure 401 and the second portion 420 of the second gate line slit structure 402 may also be arranged at intervals from each other, e.g., be disposed as being staggered from each other.

Furthermore, as shown in FIGS. 12-13, in some implementations of the present disclosure, the gate line slit structure 400 may include the first gate line slit structure 401, the second gate line slit structure 402, and a third gate line slit structure 403 located between the first gate line slit structure 401 and the second gate line slit structure 402, where the third gate line slit structure 403 extends along a direction intersecting the x-direction. In an implementation, the first gate line slit structure 401, the second gate line slit structure 402 and the third gate line slit structure 403 are arranged at intervals from each other.

The gate layer provided by some implementations of the present disclosure may be fabricated by a gate-last process. In an implementation, a stack structure (not shown) may be formed by stacking second dielectric layers and gate sacrificial layers (not shown) alternately along the z-direction. In a process of removing the gate sacrificial layer using a process such as wet etching, a gate line slit produced in forming the gate line slit structure, for example, may cause an etchant and a chemical precursor to contact the gate sacrificial layer, thereby removing a portion of the gate sacrificial layer.

In some implementations of the present disclosure above, a layout of the first gate line slit structure, the second gate line slit structure, or the third gate line slit structure in the x-y plane may be selected according to different settings of a semiconductor device architecture, so as to reduce a dimension of the gate line slit structure ultimately formed in the semiconductor device while optimizing a process window of the above operation of removing the gate sacrificial layer, and to increase the storage density of the semiconductor device.

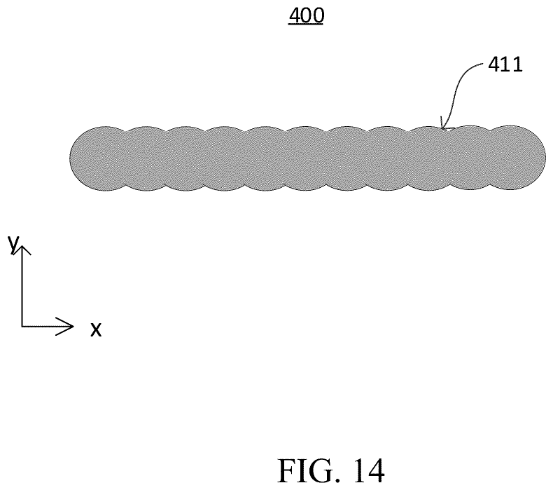

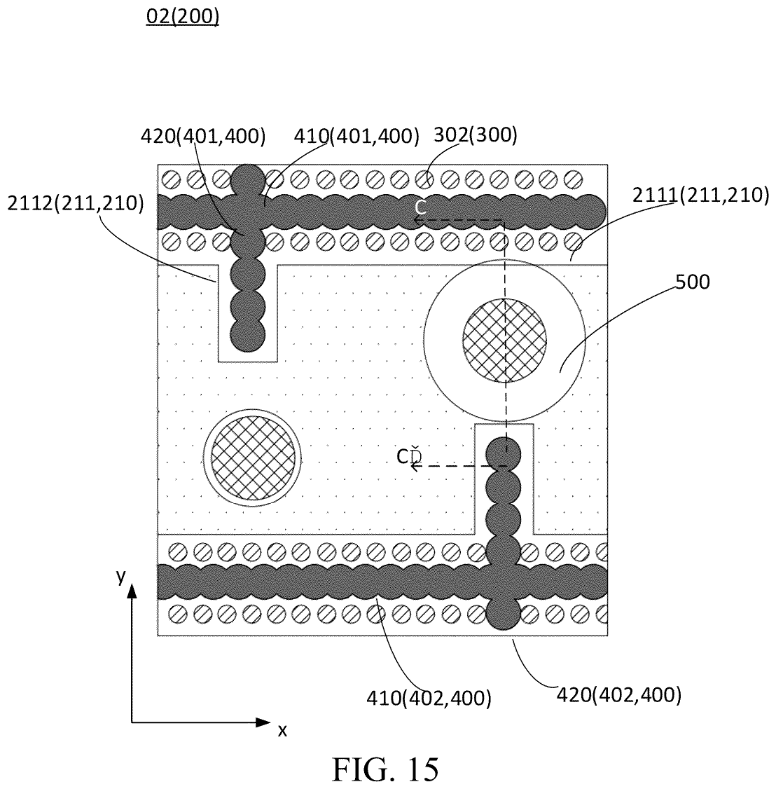

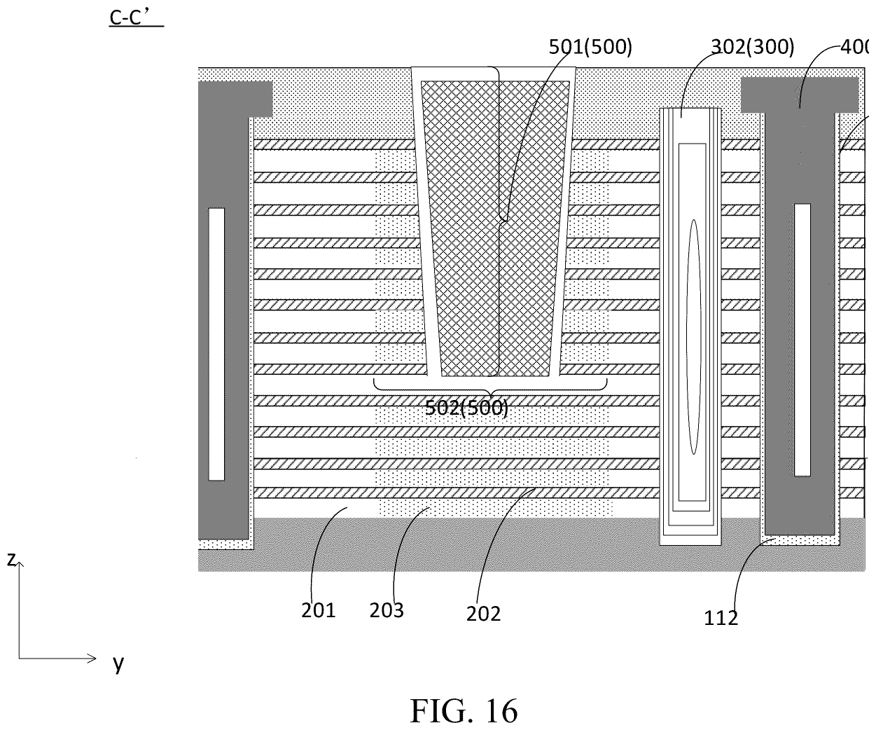

FIG. 14 is a top view of the gate line slit 400 structure, according to another implementation of the present disclosure. FIG. 15 is a local top view of the second region 02 of the stack structure 200, according to another implementation of the present disclosure. FIG. 16 is a cross-sectional view of the second region 02 shown in FIG. 15 taken along a line C-C′.

As shown in FIGS. 6-7 and 14-15, in some implementations of the present disclosure, at least one surface of the gate line slit structure 400 is a curved surface, and the curved surface includes at least one of a concave surface and a convex surface. Moreover, the gate line slit structure 400 extends in a wavy shape in a direction intersecting the z-direction.

For example, the gate line slit structure 400 includes a sidewall 411 in contact with the stack structure 200, where a surface of the sidewall 411 is a curved surface including at least one of a concave surface and a convex surface. In an implementation, the sidewall 411 of the first portion 410 of the gate line slit structure 400 has a wavy shape on both sides along the x-direction. The second portion 420 of the gate line slit structure 400 extends along a direction intersecting the x-direction, where the sidewall 411 of the second portion 420 has a wavy shape on both sides along an extending direction thereof.

In other words, in this implementation, a gate line slit accommodating the gate line slit structure 400 is formed by first forming a first hole (not shown) and then removing at least a portion of the stack structure that is located between adjacent ones of first holes. As such, a surface of a sidewall of the gate line slit that contacts the stack structure 200 is a curved surface, and accordingly, the surface of the sidewall 411 of the gate line slit structure 400 formed in the gate line slit also includes a curved surface.

In this implementation, the gate line slit accommodating the gate line slit structure 400 is formed in the following operations. The first hole formed first may be formed together with a “deep hole” of other structures in the fabricated semiconductor device 1000, and then the plurality of first holes are communicated through a “hole expanding” process to form the gate line slit. By forming various holes for different structures of the semiconductor device 1000 in a same process, such as a first channel hole, a second channel hole and the first hole, the number of etching processes for forming a structure with a high depth-to-width ratio may be reduced effectively, thereby reducing the difficulty in fabricating the semiconductor device 1000 and reducing the costs of fabricating the semiconductor device 1000.

Furthermore, the various holes for different structures of the semiconductor device 1000 may be fabricated with the same mask since they are formed in the same process, thereby improving an overlay accuracy of the etching process and reducing an overlay error, so that the semiconductor device 1000 formed ultimately has relatively high overall performance.

Moreover, as shown in FIG. 16, the gate line slit structure 400 may include a gate line isolation layer 112 located on an inner wall of the gate line slit and a gate line filling layer 111 located on a surface of the gate line isolation layer 112. In an implementation, the material for the gate line isolation layer 112 may include at least one of a high dielectric constant dielectric layer and an insulation dielectric material layer such as a silicon oxide layer. Moreover, the material for the gate line filling layer 111 may include at least one of a semiconductor material, such as polysilicon, and an insulation dielectric material layer, such as silicon oxide, silicon nitride, and silicon oxynitride. In an implementation, the material for the gate line filling layer 111 may also include a conductive material layer. The present disclosure does not limit an internal filling material of the gate line slit structure 400. It is to be noted that in figures other than FIG. 16, an internal structure of the gate line slit structure 400 is omitted in order to facilitate observation of a shape of the gate line slit structure.

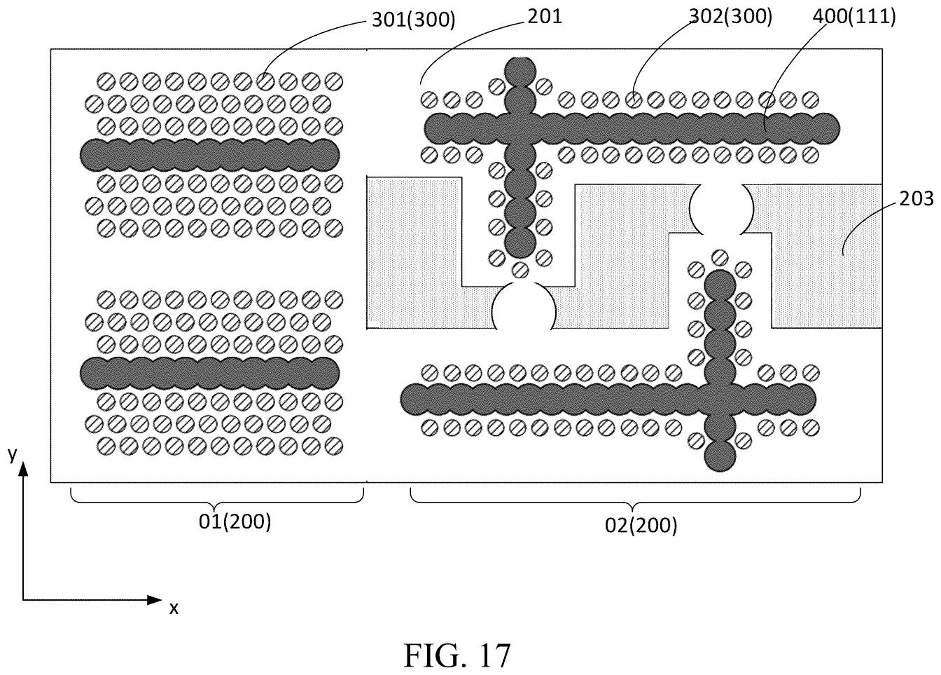

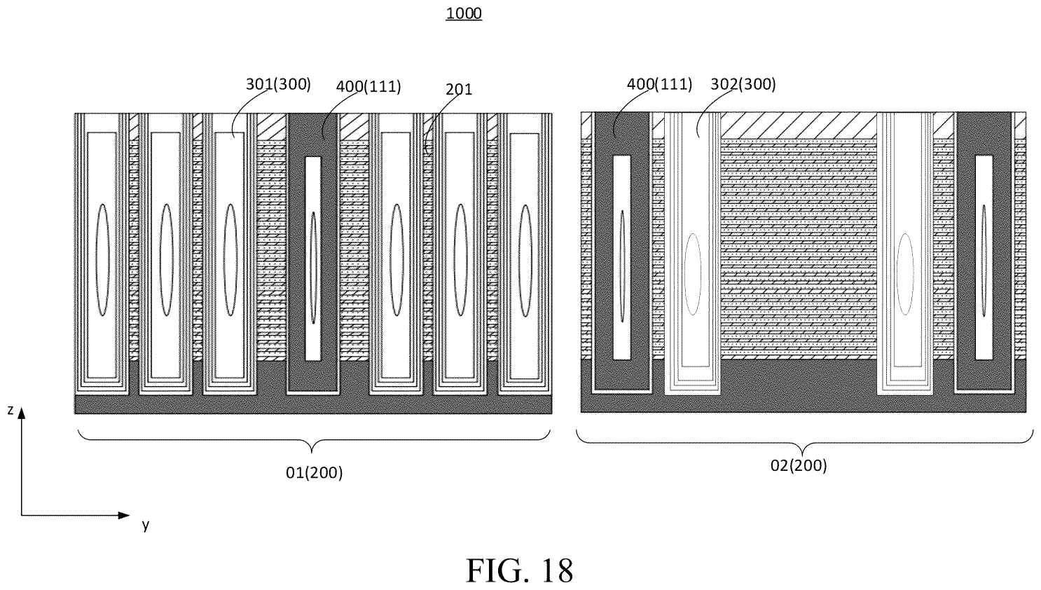

FIG. 17 is a local top view of the first region 01 and the second region 02 of the stack structure 200, according to an implementation of the present disclosure. FIG. 18 is a local cross-sectional view of the first region 01 and the second region 02 of the stack structure 200, according to an implementation of the present disclosure.

As shown in FIG. 17 and FIG. 18, the semiconductor device further includes a channel structure 300 including a first channel structure 301 and a second channel structure 302, where the first channel structure 301 may be located in the first region 01 and extends through portions of the plurality of gate layers 201 that are located in the first region 01 along the z-direction; the second channel structure 302 is located in the second region 02 and at least extends through portions of the gate layers 201 that are located in the second region 02 along the z-direction. It is to be noted that dimensions of the first channel structure 301 and the second channel structure 302 in a z-y plane are enlarged relatively in FIG. 18, so as to clearly illustrate internal structures of them.

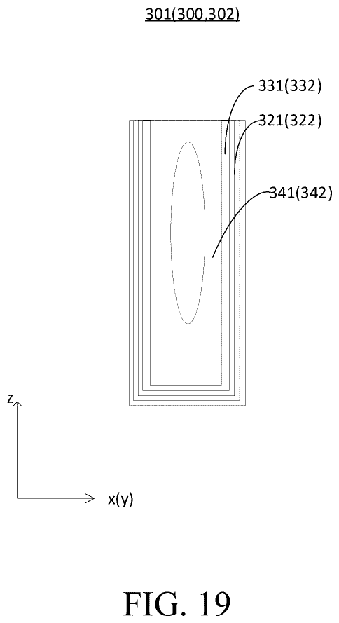

FIG. 19 is a cross-sectional view of the first channel structure 301 and the second channel structure 302, according to an implementation of the present disclosure.

In an implementation, the second channel structure 302 may include a layer structure the same as that of the first channel structure 301. For example, the first channel structure 301 may include a functional layer 321 located on an inner wall of the first channel hole (not shown) and a channel layer 331 located on a surface of the functional layer 321. The functional layer 321 may include a barrier layer, a charge trap layer and a tunneling layer disposed sequentially on an inner wall of the channel hole. The channel layer 331 may be located on a surface of the tunneling layer and may be configured to transport desired charge (electrons or holes). The channel layer 331 may be fabricated from a semiconductor material, such as polysilicon or monocrystalline silicon, and may have conductive impurities. Furthermore, the first channel structure 301 may also include a channel filling dielectric layer 341 that fills a remaining space of the channel hole where the functional layer 321 and the channel layer 331 have been formed. The channel filling dielectric layer 341 includes an insulation dielectric material, such as a silicon oxide layer.

Similarly, the second channel structure 302 may be formed in the process of forming the first channel structure 301, so as to simplify the fabrication process of the semiconductor device 1000. The second channel structure 302 may also include a first layer 322 located on an inner wall of the second channel hole (not shown) and a second layer 332 located on a surface of the first layer 322. The first layer 322 may be fabricated using the same material as the functional layer 321, and the second layer 332 may be fabricated using the same material as the channel layer 331. Furthermore, the second channel structure 302 may also a third layer 342 that fills a remaining space of the second channel hole where the first layer 322 and the second layer 332 have been formed, and the third layer 342 may be fabricated using the same material as the channel filling dielectric layer 341. As another option, the second channel structure 302 may include a layer structure different from that of the first channel structure 301, which is not limited in the present disclosure.

In an implementation, in a direction intersecting the z-direction (e.g., the x-direction or the y-direction), a dimension of the second channel structure 302 may be greater than or equal to a dimension of the first channel structure 301.

Furthermore, with reference to FIG. 8, in some implementations of the present disclosure, a plurality of second channel structures 302 may be arranged at intervals in the protrusion along the extending direction of the protrusion. For example, a plurality of second channel structures 302 are arranged at intervals in the first protrusion 2112 along an extending direction of the first protrusion 2112, and a plurality of second channel structures 302 are arranged at intervals in the second protrusion 2122 along an extending direction of the second protrusion 2122.

Additionally, with reference to FIG. 8, FIG. 10, and FIG. 12, in some implementations of the present disclosure, a plurality of second channel structures 302 may be arranged at intervals in the extension along the x-direction. For example, a plurality of second channel structures 302 are arranged at intervals in the first extension 2111 along the x-direction, and a plurality of second channel structures 302 are arranged at intervals in the second extension 2121 along the x-direction.

The second channel structure is located in the second region provided with the contact, and may play a supporting role during a process of removing the gate sacrificial layer in the stack structure, so as to reduce the possibility of deformation and collapse, etc., of the stack structure. Accordingly, a layout of the second channel structures in the x-y plane and the number of the second channel structures may be selected according to different settings of the semiconductor device architecture, so as to provide a supporting function while reducing an overall dimension of the second channel structures in the semiconductor device formed ultimately, thereby increasing the storage density of the semiconductor device.

In an implementation, with reference to FIG. 6 and FIG. 7, the contact 500 may include a contact conductive layer 510 and a contact dielectric filling layer 520 wrapped by the contact conductive layer 510, where the contact conductive layer 510 extends along the z-direction and is connected with the gate layer 201. It is be noted that in order to scale down an overall size of the figure, the internal structure of the contact 500 is not shown in some figures.

As an option, the material of the contact conductive layer 510 may include any one or a combination of a conductive metal material and a doped semiconductor material, where the conductive metal material may include, for example, tungsten (W), cobalt (Co), copper (Cu), or aluminum (Al), etc., and the doped semiconductor material may include, for example, doped crystalline silicon or silicide, etc., which are not limited in the present disclosure.

Furthermore, in an implementation of the present disclosure, the contact dielectric filling layer 520 may include, for example, a dielectric material, such as silicon oxide, silicon nitride, and silicon oxynitride. The contact includes the contact dielectric filling layer wrapped by the contact conductive layer, so that use of the conductive material in the contact may be reduced, and a reduction in the fabrication costs of the semiconductor device 1000 and a reduction in stress deformation of the stack structure 200 are achieved.

Additionally, with reference to FIG. 15, and FIG. 16, in some implementations of the present disclosure, the plurality of contacts 500 extending along the z-direction may have different extending dimensions, so as to facilitate the connections with the gate layers 201 at different stacking heights. In other words, the contact 500 is connected with the corresponding gate layer 201, so as to facilitate connecting the corresponding gate layer 201 with the external circuit (not shown) through the contact 500. The contact 500 may include two portions connected with each other, a first sub-portion 501 and a second sub-portion 502, where the first sub-portion 501 extends along the z-direction and extends to the stacking height of the gate layer 201 corresponding to the contact 500. The second sub-portion 502 extends at the stacking height of the gate layer 201 corresponding to the contact 500 along a direction (e.g., the x-direction or the y-direction) intersecting the z-direction, so as to connect the corresponding gate layer 201. It is to be noted that, when the gate layer 201 includes the same layer structure as the second sub-portion 502, there is no obvious boundary therebetween.

In an implementation, the second sub-portion 502 and the gate layer 201 may have the same thickness in the z-direction. With reference to FIG. 6, FIG. 7, FIG. 15, and FIG. 16, the first sub-portion 501 may include the contact dielectric filling layer 520. Moreover, in a direction intersecting the z-direction (e.g., the x-direction or the y-direction), the contact 500 has different dimensions at two opposite ends in the z-direction, where a dimension of an end of the contact 500 that is connected with the corresponding gate layer 201 may be greater than a dimension of the other end of the contact 500.

Therefore, in the semiconductor device according to at least one implementation of the present disclosure, the stack structure thereof includes a plurality of gate layers stacked along a first direction, where at least one gate layer extends from the first region to the second region of the stack structure along the second direction intersecting the first direction, the portion of the gate layer located in the second region includes two sub-gate layers disposed opposite to each other along the third direction intersecting both the first direction and the second direction, the sub-gate layer includes the extension extending along the second direction and the protrusion connected with extension, the protrusion of one of the sub-gate layers in a same gate layer protrudes toward the other sub-gate layer opposite thereto, and the contact extends along the first direction and is connected with both the extension and the protrusion of the corresponding gate layer. In other words, the contact may be connected with a plurality of portions of a same gate layer, thereby reducing a contact resistance between the contact and the gate layer. Furthermore, the connection of the contact with the plurality of portions of the same gate layer may reduce an extending dimension of the gate layer while ensuring the electrical performance of the semiconductor device, thereby reducing a bulk resistance of the gate layer and improving the level of integration of the semiconductor device.

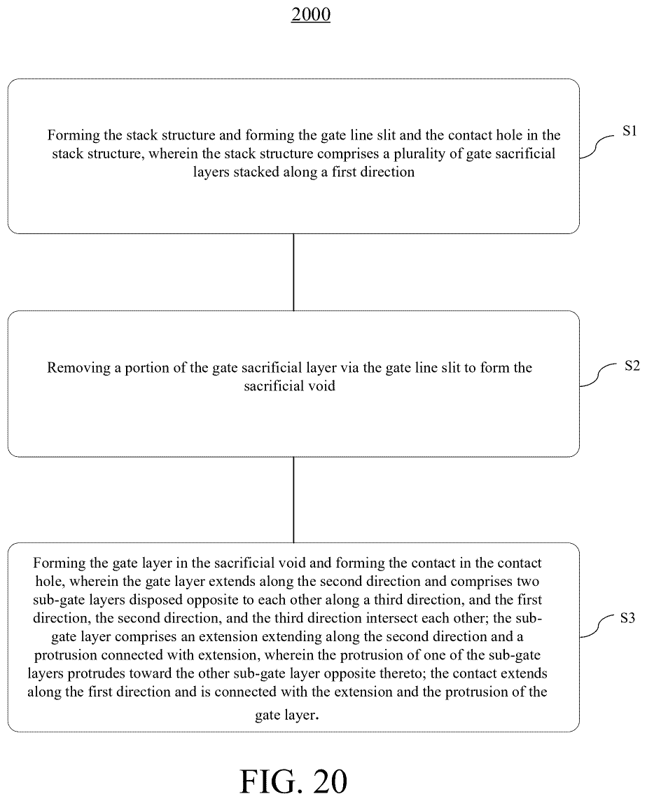

FIG. 20 is a flow diagram of a method 2000 of fabricating a semiconductor device, according to an implementation of the present disclosure. FIGS. 20-32 are respectively process diagrams of the method 2000 of fabricating a semiconductor device, according to an implementation of the present disclosure.

As shown in FIG. 20, the method 2000 of fabricating a semiconductor device may include operations S1, S2, and S3.

At operation S1, the stack structure may be formed and the gate line slit and the contact hole may be formed in the stack structure, where the stack structure includes a plurality of gate sacrificial layers stacked along a first direction.

At operation S2, a portion of the gate sacrificial layer may be removed via the gate line slit to form the sacrificial void.

At operation S3, the gate layer may be formed in the sacrificial void and forming the contact in the contact hole, where the gate layer extends along the second direction and includes two sub-gate layers disposed opposite to each other along a third direction, and the first direction, the second direction, and the third direction intersect each other; the sub-gate layer includes an extension extending along the second direction and a protrusion connected with extension, where the protrusion of one of the sub-gate layers protrudes toward the other sub-gate layer opposite thereto; the contact extends along the first direction and is connected with the extension and the protrusion of the gate layer.

Particular processes of operations of the above-mentioned method 2000 in the implementations of the present disclosure will be illustrated in detail below in conjunction with FIGS. 20-32.

### Operation S1

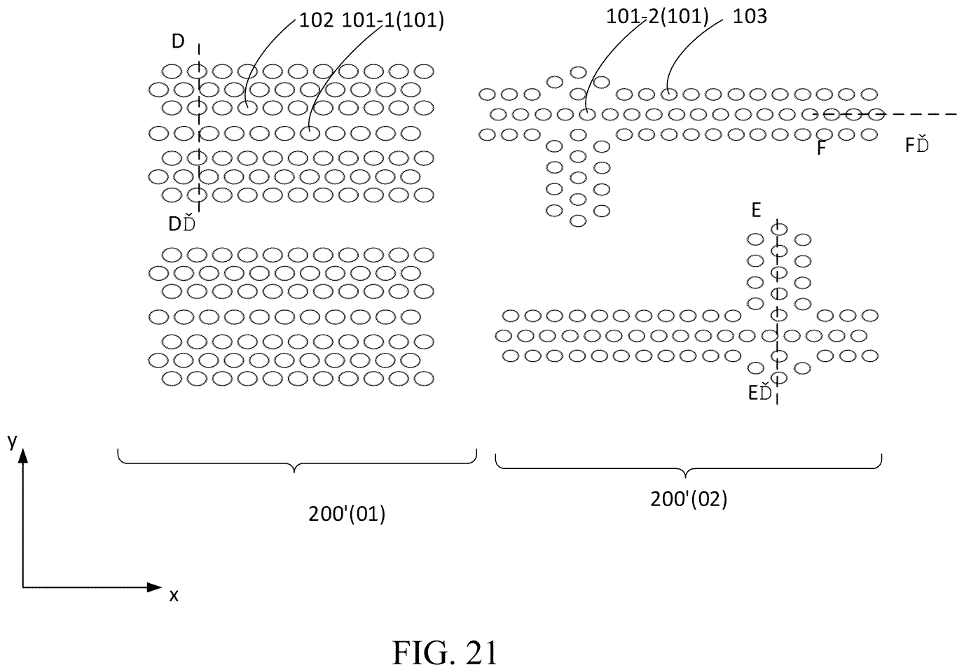

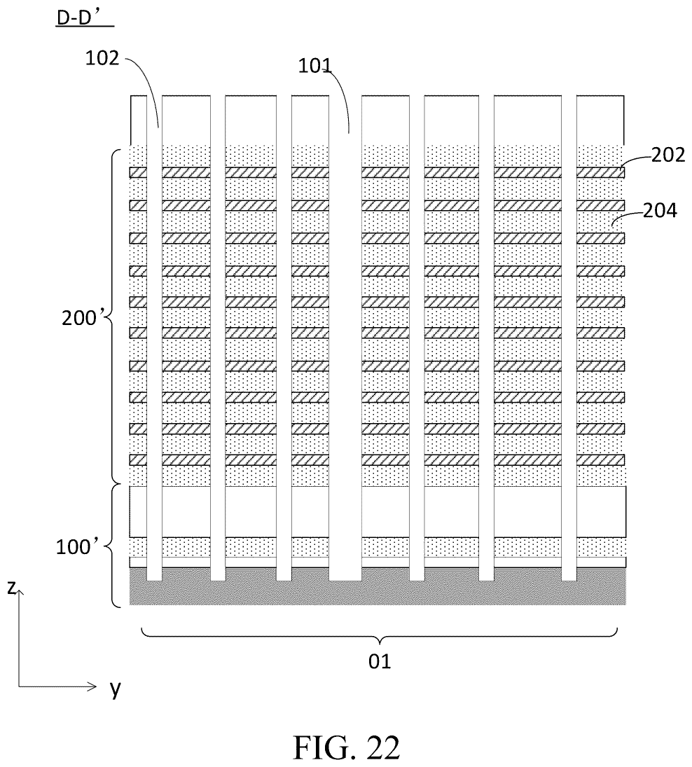

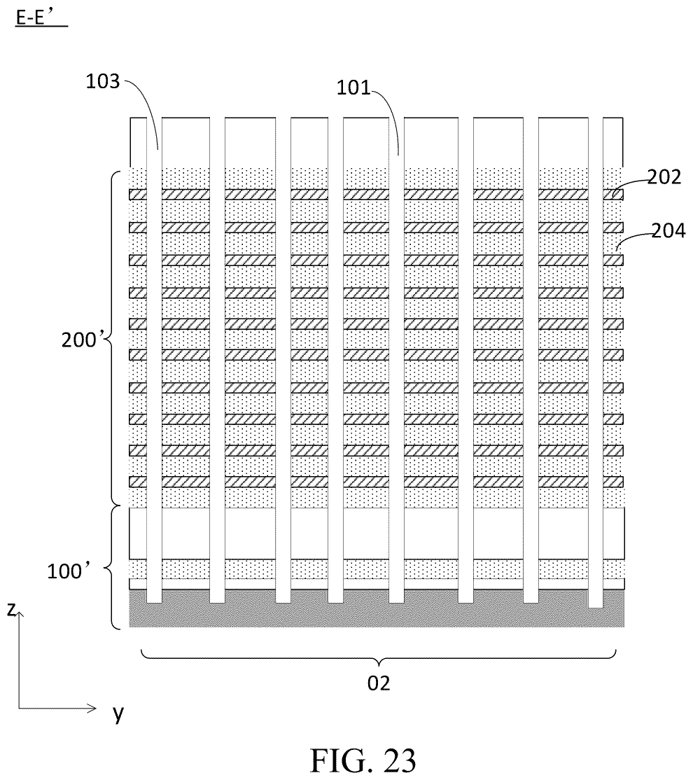

FIG. 21 is a top view of a structure formed after forming a first hole 101 of the method of fabrication, according to an implementation of the present disclosure. FIG. 22 is a cross-sectional view of the stack structure 200′ shown in FIG. 21 taken along a line D-D′. FIG. 23 is a cross-sectional view of the stack structure 200′ shown in FIG. 21 taken along a line E-E′.

As shown in FIGS. 20-23, at operation S1, the stack structure may be formed and the gate line slit and the contact hole may be formed in the stack structure, where the stack structure includes the plurality of gate sacrificial layers stacked along the first direction may include, for example, stacking the gate sacrificial layers 204 and the second dielectric layers 202 alternately to form the stack structure 200′; and forming the first hole 101 extending along the z-direction in the stack structure 200′.

In an implementation of the present disclosure, before forming the stack structure in operation S1, the method 2000 of fabricating a semiconductor device may further include providing an initial substrate 100′. The material for fabricating the initial substrate 100′ may be selected from any suitable semiconductor materials which, for example, may include monocrystalline silicon (Si), monocrystalline germanium (Ge), silicon germanium (GeSi), silicon carbide (SiC), silicon on insulator (SOI), germanium on insulator (GOI), or III-V compounds, such as gallium arsenide. As an option, monocrystalline silicon may be selected for the initial substrate 100′.

In an implementation of the present disclosure, the initial substrate 100′ may include, for example, a composite substrate for supporting device structures thereon. A plurality of layers fabricated from different materials may be sequentially disposed through a thin film deposition process, such as Chemical Vapor Deposition (CVD), Physical Vapor Deposition (PVD), Atomic Layer Deposition (ALD), or any combination thereof, so as to form the initial substrate 100′.

In an implementation of the present disclosure, the initial substrate 100′ may include a substrate sacrificial layer for subsequent formation of a semiconductor connection layer that connects the channel structure. The substrate sacrificial layer may include a single layer, a plurality of layers or a suitable composite layer. For example, the substrate sacrificial layer may include any one or more of a silicon oxide layer, a silicon nitride layer and a silicon oxynitride layer. As an option, the substrate sacrificial layer may include a high dielectric constant dielectric layer. As another option, the substrate sacrificial layer may include a dielectric layer, a sacrificial layer and a dielectric layer disposed sequentially, where the dielectric layer may include a silicon nitride layer, and the sacrificial layer may include a silicon oxide layer. As yet another option, the substrate sacrificial layer may include any one or more of a dielectric material, a semiconductor material and a conductive material. For example, the sacrificial layer may include monocrystalline silicon or polysilicon. In an implementation of the present disclosure, an example material for forming the sacrificial layer may include polysilicon.

Part of a region of the initial substrate 100′ may also form a well region formed by doping with an N or P-type dopant via an ion implantation or diffusion process. The dopant may include any one or a combination of phosphorus (P), arsenic (As) and antimony (Sb); or any one or a combination of boron (B), gallium (Ga) or indium (In). In some implementations of the present disclosure, the well region may be fabricated using the same dopant, or fabricated using different dopants. Furthermore, the well region may have the same doping concentration or different doping concentrations, which are not limited by the present disclosure.

After forming the initial substrate 100′, the stack structure 200′ may be formed on the initial substrate through one or more thin film deposition processes. The thin film deposition process may include, but is not limited to, chemical vapor deposition (CVD), physical vapor deposition (PVD), atomic layer deposition (ALD), or any combination thereof, which is not limited by the present disclosure.

The stack structure 200′ may include a plurality of pairs of gate sacrificial layers 204 and second dielectric layers 202 stacked alternately. For example, the stack structure 200′ may include 64 pairs, 128 pairs, or more than 128 pairs of gate sacrificial layers 204 and second dielectric layers 202.

In some implementations, the gate sacrificial layer 204 and the second dielectric layer 202 may include a first dielectric material and a second dielectric material different from the first dielectric material respectively. Example materials for forming the gate sacrificial layer 204 and the second dielectric layer 202 may include silicon nitride and silicon oxide, respectively. The silicon oxide layer may be used as an isolation stacking layer, and the silicon nitride layer may be used as a sacrificial stacking layer. Subsequently, a portion of the sacrificial stacking layer may be etched off, and a conductor layer including a conductive material may be configured to replace the etched-off portion of the sacrificial stacking layer, so as to form the gate layer of the semiconductor device.

Moreover, the stack structure 200′ may further include a cover layer which is located at a highest stacking portion of the stack structure 200′. The cover layer includes, but is not limited to, an insulation dielectric material layer, such as a silicon oxide layer.

The method of fabricating a single stack structure is described above. In fact, a storage stack increases gradually as the demand for the storage capacity of the semiconductor device increases constantly. In order to break through restrictions of limits of the process, a double-stacking technique or a multi-stacking technique may be configured to form the stack structure formed by a plurality of stack sub-structures that are stacked sequentially in a thickness direction of the stack structure, where each stack sub-structure may include a plurality of gate sacrificial layers and second dielectric layers stacked alternately. The stack sub-structures may have the same or different numbers of layers. Since contents and structures involved in the fabrication process of a single stack structure described above is completely or partially applicable to the stack structure including the formation of a plurality of stack sub-structures described here, contents related or similar thereto are no longer repeated here. However, those skilled in the art may understand that subsequent fabrication processes may be performed based on the plurality of stack structures or the single stack structure.

Furthermore, in an implementation of the present disclosure, operation S1 of forming the stack structure may further include: forming the first channel structure (not shown) and the second channel structure (not shown) in the stack structure 200′; and forming the gate line slit (not shown) in the stack structure 200′.

In an implementation, the stack structure 200′ may include the first region 01 and the second region 02 arranged adjacent to each other along the x-direction, the first channel structure extending along the z-direction may be formed in the first region 01, and the second channel structure extending along the z-direction may be formed in the second region 02.

In an implementation of the present disclosure, forming the first channel structure includes: forming the first channel hole 102 extending in the stack structure 200′ along the z-direction, and forming the first channel structure in the first channel hole 102. Moreover, forming the second channel structure may include: forming the second channel hole 103 extending in the stack structure 200′ along the z-direction, and forming the second channel structure in the second channel hole 103.

In an implementation of the present disclosure, the gate line slit may be formed in operations. For example, the first holes 101 are formed first, and then the plurality of first holes 101 are communicated through the “hole expanding” process to form the gate line slit.

As an option, the first hole 101 may be formed together with the “deep holes” of other structures in the fabricated semiconductor device 1000. For example, the first hole 101 may be formed in the same process as the first channel hole 102 and the second channel hole 103.

In an implementation, the first hole 101, the first channel hole 102 and the second channel hole 103 may be formed by a dry etching process or a combination of dry and wet etching processes. Furthermore, other manufacturing processes, such as a patterning process including lithography, cleaning and chemical mechanical polishing, may also be performed to remove a portion of the stack structure 200′, thereby forming the first hole 101, the first channel hole 102, and the second channel hole 103.

In an implementation, the first hole 101, the first channel hole 102 and the second channel hole 103 may have the same extending dimension in the z-direction, so as to reduce the process difficulty in fabricating a plurality of “deep holes”.

By forming a variety of holes for different structures of the semiconductor device in a same process, such as the first channel hole, the second channel hole, and the first hole, the number of etching processes used for forming a structure with a high depth-to-width ratio may be reduced effectively, thereby reducing the difficulty in fabricating the semiconductor device and reducing the costs of fabricating the semiconductor device.

Furthermore, the variety of holes for different structures of the semiconductor device may be fabricated with the same mask since they are formed in the same process, thereby improving an overlay accuracy of the etching process and reducing an overlay error, so that the semiconductor device formed ultimately has relatively high overall performance.

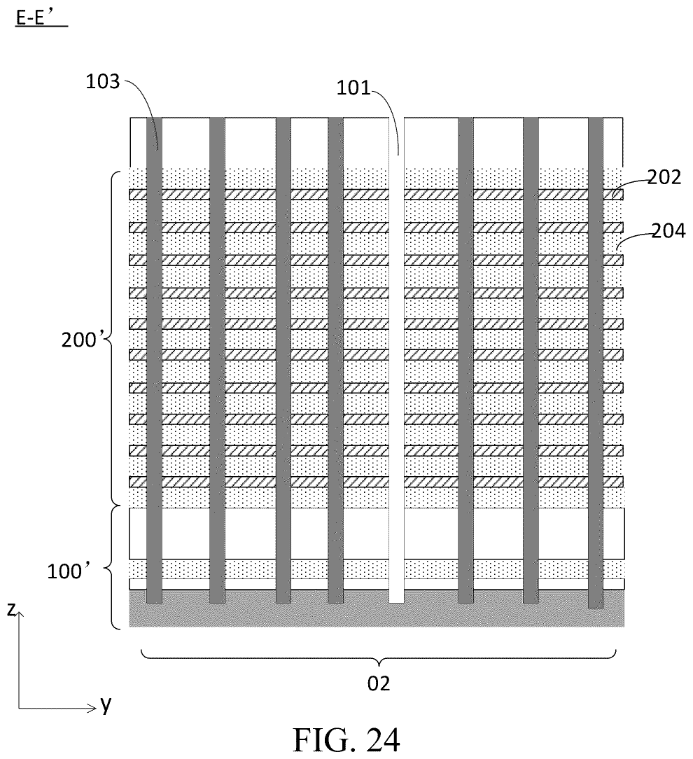

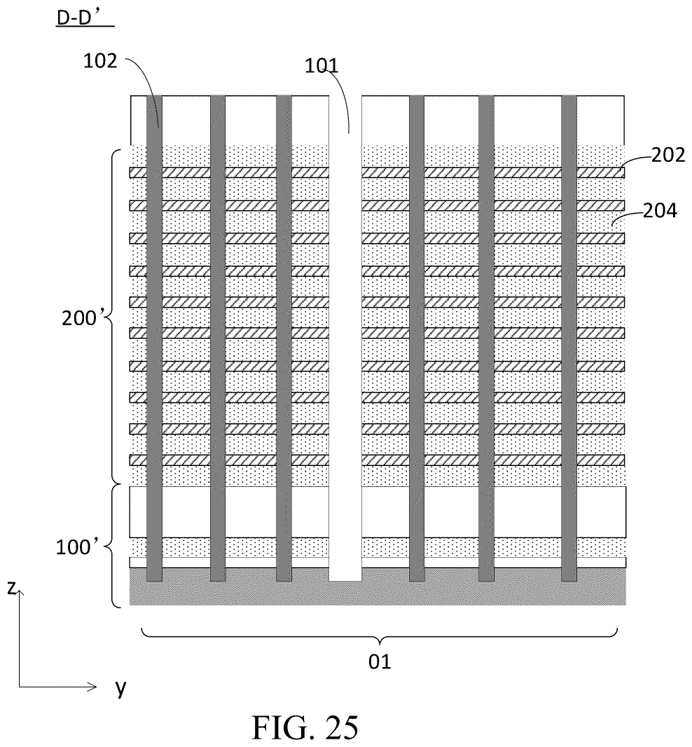

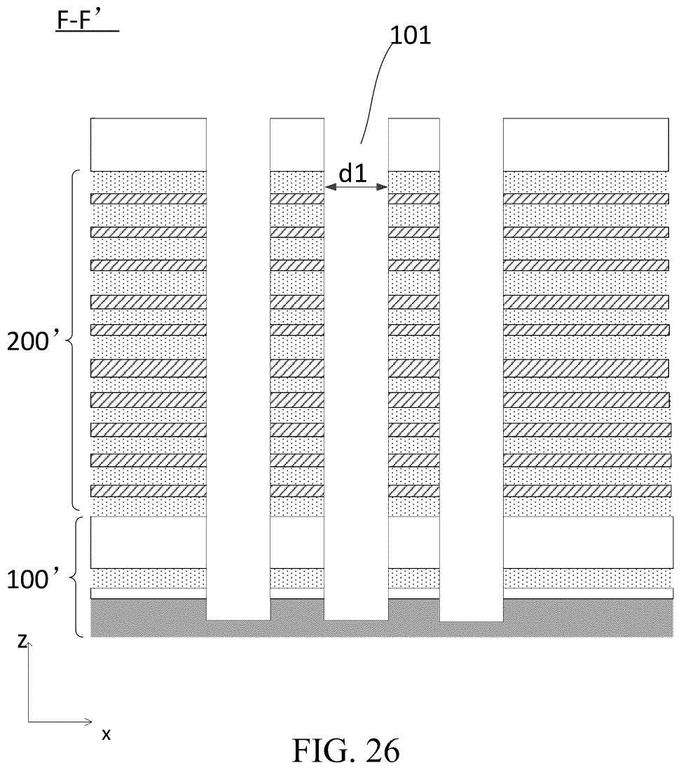

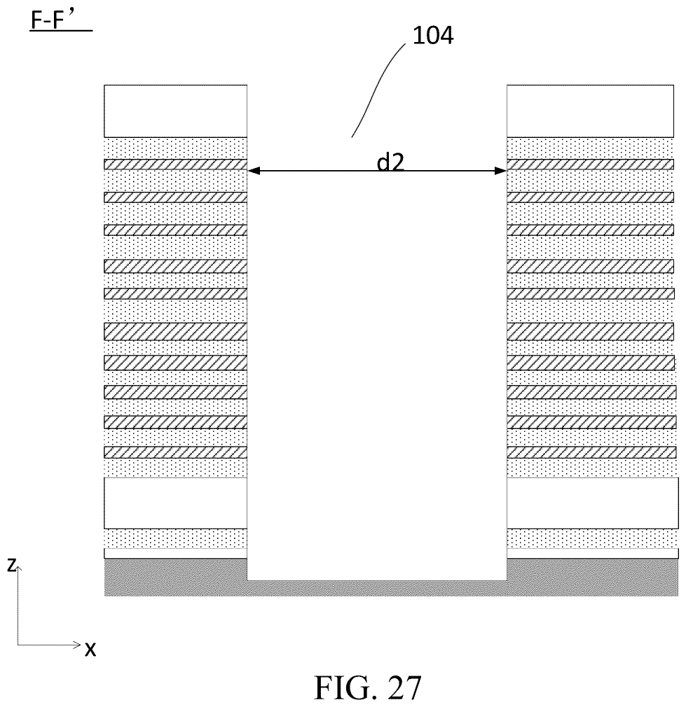

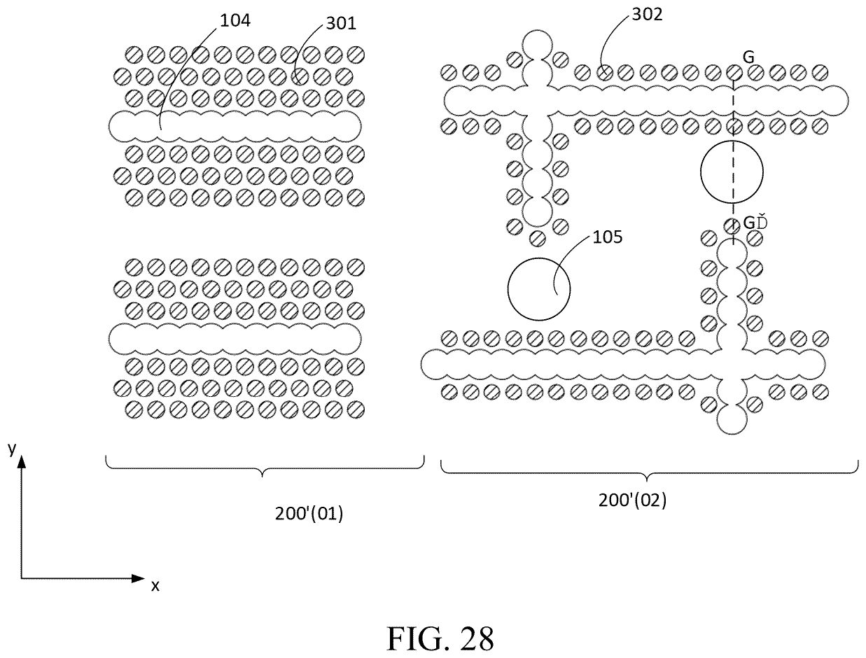

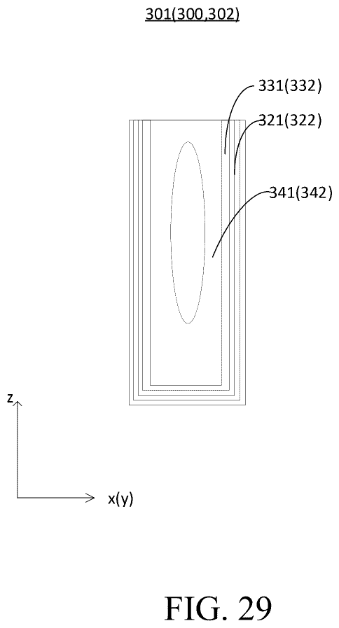

FIG. 24 is a cross-sectional view of a structure formed after filling the first channel hole 102 of the method of fabrication, according to an implementation of the present disclosure. FIG. 25 is a cross-sectional view of a structure formed after filling the second channel hole 103 of the method of fabrication, according to an implementation of the present disclosure. FIG. 26 is a cross-sectional view of the stack structure 200′ shown in FIG. 21 taken along a line F-F′ after completing the filling of the first channel hole 102 and the second channel hole 103. FIG. 27 is a cross-sectional view of a structure formed after forming the gate line slit 104 following the “hole expanding” of the first holes 101 shown in FIG. 26. FIG. 28 is a cross-sectional view of a local structure formed after forming the first channel structure 301 and the second channel structure 302 of the method fabrication, according to an implementation of the present disclosure. FIG. 29 is a cross-sectional view of a structure formed after forming the first channel structure 301 and the second channel structure 302 of the method fabrication, according to an implementation of the present disclosure.

As shown in FIGS. 21-29, after forming the first holes 101, the gate line slit 104 may be formed through the “hole expanding” process.

In an implementation, as shown in FIGS. 21-26, a first sacrificial layer is formed in a plurality of first channel holes 102, a plurality of second channel holes 103 and a plurality of first holes 101 through a thin film deposition process, such as chemical vapor deposition (CVD), physical vapor deposition (PVD), atomic layer deposition (ALD), or any combination thereof. The first sacrificial layer may include a carbon-containing material layer. The first sacrificial layer may be formed from a material having a high deposition rate, so as to facilitate rapid filling of the variety of holes described above. The first sacrificial layer should be any material having higher dry etch selectivity relative to the second dielectric layer 202 and the gate sacrificial layer 204, so as to facilitate removal in the subsequent operations.

After forming the first sacrificial layer, the first sacrificial layer in the first hole 101 may be removed through, for example, a dry etching process or a combination of dry and wet etching processes, or other manufacturing processes, such as a patterning process including lithography, cleaning and chemical mechanical polishing, so as to facilitate hole expanding processing on the exposed first hole 101.

With reference to FIG. 21 and FIG. 26, the plurality of first holes 101 include a plurality of first region first holes 101-1 located in the first region 01 and a plurality of second region first holes 101-2 located in the second region 02, where the plurality of first region first holes 101-1 are arranged at intervals along the x-direction, a part of the plurality of second region first holes 101-2 are arranged at intervals along the x-direction, and the other part of the plurality of second region first holes 101-2 are arranged at intervals along a direction intersecting the x-direction (e.g., the y-direction).

With reference to FIG. 21, FIG. 26, FIG. 27, and FIG. 29, in an implementation of the present disclosure, at least a portion of the stack structure 200′ located between adjacent ones of the first holes 101 is removed through, for example, a dry etching process or a combination of dry and wet etching processes, or other manufacturing processes, such as a patterning process including lithography, cleaning and chemical mechanical polishing, so as to form the gate line slit 104.

As an option, the first hole 101 may be expanded or extended in operations along a plurality of directions, so as to form the gate line slit 104. For example, as shown in FIG. 26 and FIG. 27, a portion of the stack structure 200′ may be removed along a radial direction of the first hole 101, so that a hole diameter of the portion of the first hole 101 which is located in the stack structure 200′ is expanded from d1 to d2 in the x-direction. Afterwards, a portion of the initial substrate 100′ may be removed continuously along the radial direction of the first hole 101, so that a hole diameter of the portion of the first hole 101 which is located in the initial substrate 100′ is also expanded from d1 to d2 in the x-direction, thereby forming the gate line slit 104.

As shown in FIG. 28 and FIG. 29, after forming the gate line slit 104, the gate line slit 104 may be filled with a second sacrificial layer (not shown), so as to facilitate forming the first channel structure 301 and the second channel structure 302 in the first channel hole 102 (as shown in FIG. 21) and the second channel hole 103 (as shown in FIG. 21), respectively. A process for forming the second sacrificial layer includes a thin film deposition process, such as chemical vapor deposition (CVD), physical vapor deposition (PVD), atomic layer deposition (ALD), or any combination thereof.

In an implementation, as shown in FIGS. 21-29, a dry etching process or a combination of dry and wet etching processes is used. Furthermore, other manufacturing processes, such as a patterning process including lithography, cleaning, and wet etching, may also be performed to remove the first sacrificial layer in the first channel hole 102 and the second channel hole 103. Subsequently, through a thin film deposition process, e.g., such as chemical vapor deposition (CVD), physical vapor deposition (PVD), atomic layer deposition (ALD), or any combination thereof, the functional layer 321 and the channel layer 331 may be formed on the inner wall of the first channel hole 102, and the first layer 322 and the second layer 332 may be formed on the inner wall of the second channel hole 103. The functional layer 321 and the channel layer 331 form the first channel structure 301, and the first layer 322 and the second layer 332 form the second channel structure 302.

The functional layer 321 may include: a barrier layer (not shown) formed on the inner wall of the first channel hole 102 for blocking a flow of charge, a charge trap layer (not shown) formed on a surface of the barrier layer for storing charge during operations of the semiconductor device, and a tunneling layer (not shown) formed on a surface of the charge trap layer.

In some implementations, the functional layer 321 may include an oxide-nitride-oxide (ONO) structure. However, in some other implementations, the functional layer 321 may have a structure different from an ONO configuration. The channel layer 331 may be formed on a surface of the tunneling layer and may be configured to transport desired charge (electrons or holes).

However, those skilled in the art may understand that, in case of not departing from the teaching of the present disclosure, the functional layer may be formed on a sidewall and a bottom surface of the first channel hole or on a sidewall of the first channel hole depending on different semiconductor device architectures, which is not limited by the present disclosure.

In some implementations, the channel layer 331 may be fabricated from a semiconductor material, such as polysilicon or monocrystalline silicon, and may have conductive impurities. For example, the channel layer 331 may be an N-type doped or P-type doped polysilicon layer. The channel layer 331 may have a cylinder or pillar shape extending in the stack structure 200′ along the z-direction.

Moreover, the first channel structure 301 further includes a channel plug (not shown) formed at an end of the first channel structure 301 with a channel hole. In an implementation, the first channel structure 301 may be filled with the channel filling dielectric layer 341 after forming the functional layer 321 and the channel layer 331. The channel filling dielectric layer 341 may include an oxide dielectric layer, such as silicon oxide. Furthermore, during the filling process, a plurality of insulation voids may be formed in the channel filling dielectric layer 341 by controlling the channel filling process, so as to alleviate a structural stress. Then, the channel plug is formed in a portion of the channel filling dielectric layer 341 that is located at an end of the first channel structure 301 with the channel hole. The channel plug may be fabricated from the same material as the channel layer 331, such as N-type doped or P-type doped polysilicon. The channel plug is connected with the channel layer 331.

In the process of forming the first channel structure 301, the first layer 322, the second layer 332, and the third layer 342 of the second channel structure 302 may be formed by a method the same as that described above, and therefore, contents related or similar thereto are no longer repeated. It is to be noted that, as the second channel structure 302 does not have a storage function, the second channel structure 302 does not require formation of a layer structure similar to the channel plug.

Furthermore, as an option, as the second channel structure 302 does not have a storage function, the second channel hole 103 may be filled with only an insulation dielectric material layer, such as a silicon oxide layer, through a thin film deposition process such as chemical vapor deposition (CVD), physical vapor deposition (PVD), atomic layer deposition (ALD), or any combination thereof. Similarly, a plurality of insulation voids may be formed in the third layer 342 by controlling the channel filling process, so as to alleviate the structural stresses of the second channel structure 302.

As shown in FIG. 29, the gate line slit 104 includes a sidewall 1041 in contact with the stack structure 200′, where a surface of the sidewall 1041 is a curved surface including at least one of a concave surface and a convex surface. In an implementation, a sidewall of a portion of the gate line slit 104 that is located in the first region 01 has a wavy shape on both sides along the x-direction. A part of a portion of the gate line slit 104 that is located in the second region 02 extends along the x-direction, and the other part extends in a direction intersecting the x-direction, where a sidewall of the portion of the gate line slit 104 that is located in the second region 02 has a wavy shape on both sides along an extending direction thereof.

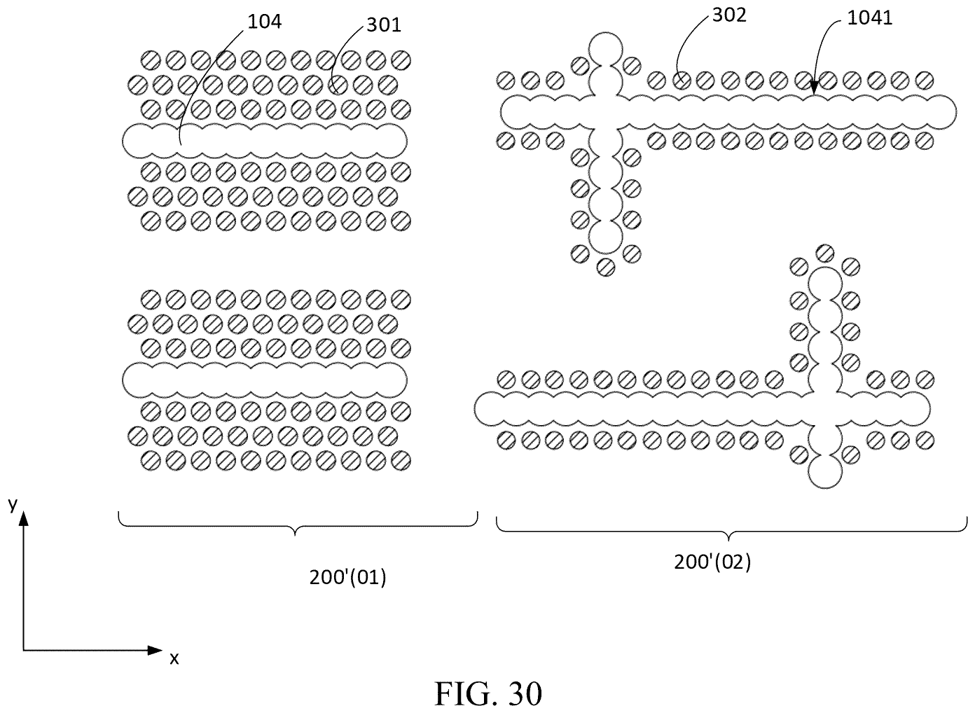

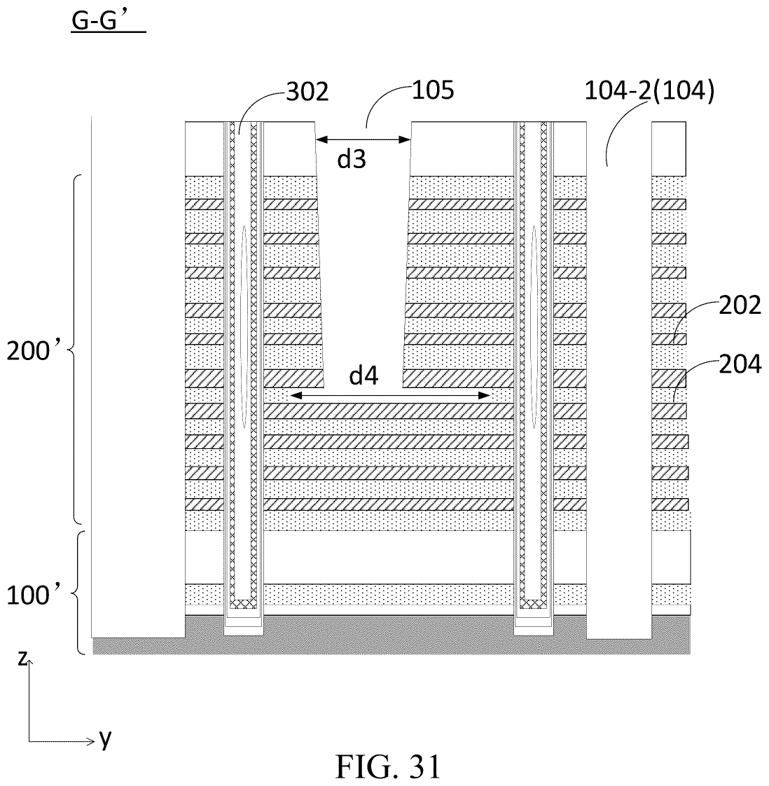

FIG. 30 is a cross-sectional view of a structure formed after forming the contact hole 105 of the method fabrication, according to an implementation of the present disclosure. FIG. 31 is a cross-sectional view of the stack structure 200′ shown in FIG. 30 taken along a line G-G′ after forming the contact hole 105.

As shown in FIG. 30 and FIG. 31, in some implementations of the present disclosure, a dry etching process or a combination of dry and wet etching processes may be used. Furthermore, other manufacturing processes, such as a patterning process including lithography, cleaning and chemical mechanical polishing, may also be performed to remove a portion of the stack structure 200′, so as to form the contact hole 105. The contact hole 105 is located in the second region 02 and may be configured to accommodate the contact formed subsequently.

In some implementations of the present disclosure, a plurality of contact holes 105 extending along the z-direction may have different extending dimensions, so as to facilitate the connections with the gate sacrificial layers 204 at different stacking heights. In other words, the contact formed subsequently in the contact hole 105 may be connected with the corresponding gate layer, so as to facilitate connecting the corresponding gate layer with the external circuit through the contact. Accordingly, the plurality of contact holes 105 may all extend along the z-direction and may extend to the gate sacrificial layers 204 at different stacking heights.

In an implementation, a dry etching process or a combination of dry and wet etching processes may be used. Furthermore, other manufacturing processes, such as a patterning process including lithography, cleaning and chemical mechanical polishing, may also be performed to remove a portion of the stack structure 200′, thereby forming the “deep holes” extending along the z-direction to the gate sacrificial layers 204 at different stacking heights. The “deep hole” includes a first end and a second end opposite to each other in the z-direction, where the second end is closer to the initial substrate 100′ than the first end. A radial dimension of the first end is greater than a radial dimension of the second end, e.g., a dimension d3 of the first end in the y-direction is greater than a dimension of the second end in the y-direction.

After forming the “deep hole”, a dry etching process or a combination of dry and wet etching processes may be continued for the formation. Furthermore, other manufacturing processes, such as a patterning process including lithography, cleaning and chemical mechanical polishing, may also be performed to remove a portion of the stack structure 200′ in a radial direction along the second end of the “deep hole”, so that a dimension d4 of an end of the final contact hole 105 that is close to the initial substrate 100′ in the y-direction is greater than the dimension d3 of the first end in the y-direction.

### Operation S2

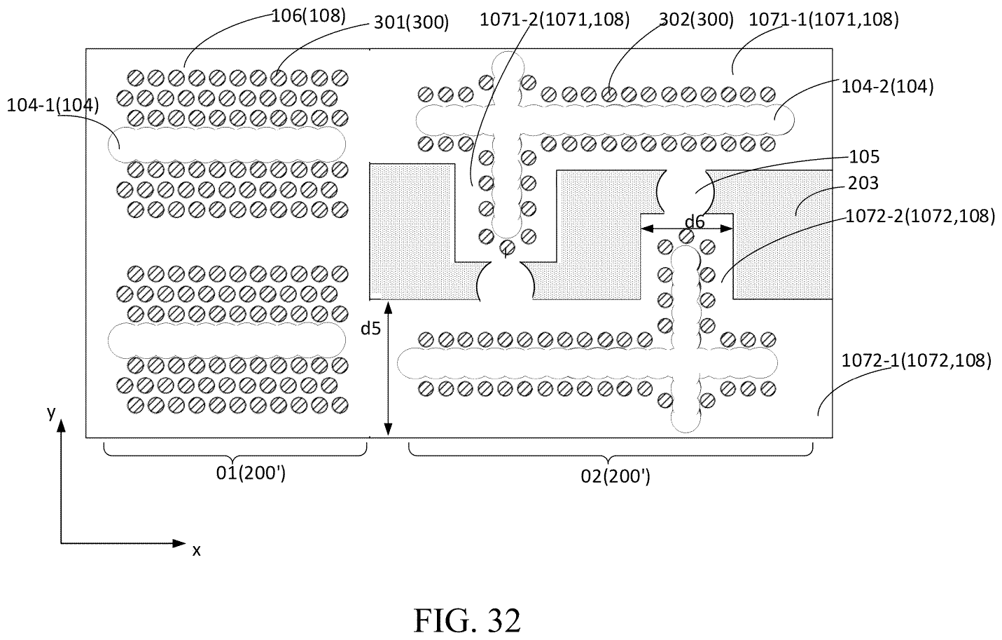

FIG. 32 is a cross-sectional view of a structure formed after forming the sacrificial void 108 of the method fabrication, according to an implementation of the present disclosure.

As shown in FIGS. 30-32, at operation S2, removing a portion of the gate sacrificial layer via the gate line slit to form the sacrificial void may include, e.g., forming two sacrificial sub-voids disposed opposite to each other along the y-direction, e.g., a second sacrificial sub-void 1071 and a third sacrificial sub-void 1072, where each sacrificial sub-void includes a first void extending along the x-direction and a second void communicated with the first void, and the second void of a sacrificial sub-void protrudes toward the other sacrificial sub-void opposite thereto.

In an implementation of the present disclosure, the gate line slit 104 may include a portion located in the first region 01 of the stack structure 200′, e.g., a first gate line slit 104-1. In addition, the gate line slit 104 may further include a portion located in the second region 02 of the stack structure 200′, e.g., a second gate line slit 104-2. In an implementation, the gate line slit 104 may further include a third gate line slit (not shown) extending from the first region 01 to the second region 02 along the x-direction.

As an option, the portion of the gate sacrificial layer 204 located in the first region 01 and the portion located in the second region 02 may be removed in operations. For example, the portion of the gate sacrificial layer 204 located in the first region 01 is removed by means of portions of the first gate line slit 104-1 and the third gate line slit that are located in the first region 01. In this process, portions of the second gate line slit 104-2 and the third gate line slit that are located in the second region 02 may be filled, and the portions of the first gate line slit 104-1 and the third gate line slit that are located in the first region 01 may serve as a pathway for the etchant and the chemical precursor, so as to remove the portion of the gate sacrificial layer 204 located in the first region 01 using, for example, an isotropic etching process such as wet etching, thereby forming the first sacrificial sub-void 106.

Moreover, in the process of filling the portions of the second gate line slit 104-2 and the third gate line slit that are located in the second region 02, the formed contact holes 105 may be filled using the same process.

Then, the first sacrificial sub-void 106 and the portions of the first gate line slit 104-1 and the third gate line slit that are located in the first region 01 may be filled, and the portions of the second gate line slit 104-2 and the third gate line slit that are located in the second region 02 and the contact hole 105 may be exposed again by performing, for example, a dry etching process or a combination of dry and wet etching processes, or other manufacturing processes, such as a patterning process including lithography, cleaning and chemical mechanical polishing. The second sacrificial sub-void 1071 and the third sacrificial sub-void 1072 located in the second region 02 of the stack structure 200′ are formed by using the process described above or a similar process.

Furthermore, in the process of removing a portion of the gate sacrificial layer 204 using, for example, a process such as wet etching, process parameters such as the type of the etchant in the gate line slit 104, a concentration of the etchant, etching time, and an etching rate are adjustable. As such, in the process of etching the portion of the gate sacrificial layer 204, a portion of the gate sacrificial layer 204 located in the first region 01, a portion of the gate sacrificial layer 204 that is located in the second region 02 and adjacent to the gate line slit 104, and a portion of the gate sacrificial layer 204 that is located in the second region 02 and adjacent to the contact hole 105 may be fully etched, and no insufficient etching occurs; and it is ensured that a portion of the gate sacrificial layer 204 in the second region 02 of the stack structure may be retained accurately during the etching process, thereby improving over-etching. A retained portion of the gate sacrificial layer 204 forms the first dielectric layer 203, and the first dielectric layer 203 is disposed in the same layer as the gate layer formed subsequently.

The first sacrificial sub-void 106, the second sacrificial sub-void 1071, and the third sacrificial sub-void 1072 are communicated with each other to form the sacrificial void 108, and the sacrificial void 108 may be configured to form the gate layer.

In an implementation, the second sacrificial sub-void 1071 and the third sacrificial sub-void 1072 are disposed opposite to each other in the y-direction, where the second sacrificial sub-void 1071 and the third sacrificial sub-void 1072 both include the first void extending along the x-direction and the second void communicated with the first void. For example, the first void 1071-1 of the second sacrificial sub-void 1071 extends along the x-direction and is communicated with the second void 1071-2 of the second sacrificial sub-void 1071. The first void 1072-1 of the third sacrificial sub-void 1072 extends along the x-direction and is communicated with the second void 1072-2 of the third sacrificial sub-void 1072.

Furthermore, the second void 1071-2 of the second sacrificial sub-void 1071 protrudes toward the third sacrificial sub-void 1072, and the second void 1072-2 of the third sacrificial sub-void 1072 protrudes toward the second sacrificial sub-void 1071.

In some implementation of the present disclosure, with reference to FIG. 1, FIG. 2, and FIG. 32, a width of the first void may be greater than or equal to a width of the second void in a plane intersecting the z-direction (e.g., the x-y plane). For example, a width d5 of the first void 1072-1 of the third sacrificial sub-void 1072 may be greater than or equal to a width d6 of the second void 1072-2 of the third sacrificial sub-void 1072, so that gate layers of different dimensions may be formed through a subsequent gate layer formation process, so as to adapt to semiconductor devices of different architectures, where the width may be understood as a dimension of each void in a direction perpendicular to a respective extending direction thereof.

### Operation S3

With reference to FIGS. 1-3 and FIG. 32, at operation S3, forming the gate layer in the sacrificial void and forming the contact in the contact hole may include, e.g., forming the gate layer 201 and the contact 500 in the same process.

In some implementations of the present disclosure, after forming the sacrificial void 108, the gate layer 201 may be formed in the sacrificial void 108 through a thin film deposition process, such as chemical vapor deposition (CVD), physical vapor deposition (PVD), atomic layer deposition (ALD), or any combination thereof. The gate layer 201 may include a conductive material, such as any one of or any combination of tungsten (W), cobalt (Co), copper (Cu), aluminum (Al), doped crystalline silicon, or silicide.

In an implementation, with reference to FIGS. 1-3, FIGS. 6-7, and FIG. 32, the contact 500 may include the contact conductive layer 510 and the contact dielectric filling layer 520 wrapped by the contact conductive layer 510, where the contact conductive layer 510 extends along the z-direction and is connected with the gate layer 201. The material for the contact conductive layer 510 may be the same as the material for the gate layer 201. The contact dielectric filling layer 520 may include, for example, a dielectric material such as silicon oxide, silicon nitride, and silicon oxynitride. The contact includes the contact dielectric filling layer wrapped by the contact conductive layer, so that use of the conductive material in the contact may be reduced, and the effects of reducing the fabrication costs of the semiconductor device and reducing stress deformation are achieved.

Moreover, before forming the gate layer 201, the method 2000 of fabricating a semiconductor device according to an implementation of the present disclosure further includes forming an isolation dielectric layer (not shown) on an inner wall of the sacrificial void 108 and on an inner sidewall of the gate line slit 104 by using a thin film deposition process such as chemical vapor deposition (CVD), physical vapor deposition (PVD), atomic layer deposition (ALD), or any combination thereof. As an option, the isolation dielectric layer may include a high dielectric constant dielectric layer. Furthermore, an adhesion layer (not shown) may be formed between the second dielectric layer 202 and the gate layer 201 or between the isolation dielectric layer and the gate layer 201 by using a thin film deposition process such as chemical vapor deposition (CVD), physical vapor deposition (PVD), atomic layer deposition (ALD), or any combination thereof. The adhesion layer may include, for example, a titanium nitride (TiN) layer.

Furthermore, with reference to FIGS. 14-18 and FIG. 32, in some implementations of the present disclosure, after forming the gate layer 201, the gate line slit structure 400 may be formed by filling the gate line slit 104. In an implementation, the gate line slit structure 400 is formed by filling the gate line slit 104 with the gate line isolation layer 112 and the gate line filling layer 111 sequentially, using a thin film deposition process such as chemical vapor deposition (CVD), physical vapor deposition (PVD), atomic layer deposition (ALD), or any combination thereof. The gate line filling layer 111 may be selected from an insulation dielectric material such as silicon oxide, silicon nitride, and silicon oxynitride, or a semiconductor material such as polysilicon, which is not limited by the present disclosure. After forming the gate line slit structure 400 and the gate layer 230 in the stack structure 200′, the stack structure 200′ forms the stack structure 200.

Therefore, for the method of fabricating a semiconductor device provided according to at least one implementation of the present disclosure, the stack structure of the semiconductor device includes a plurality of gate layers stacked along a first direction, where at least one gate layer extends from the first region of the stack structure to the second region along the second direction intersecting the first direction, the portion of the gate layer located in the second region includes two sub-gate layers disposed opposite to each other along the third direction intersecting both the first direction and the second direction, the sub-gate layer includes the extension extending along the second direction and the protrusion connected with extension, the protrusion of one of the sub-gate layers in a same gate layer protrudes toward the other sub-gate layer opposite thereto, and the contact extends along the first direction and is connected with both the extension and the protrusion of the corresponding gate layer. In other words, the contact may be connected with a plurality of portions of the same gate layer, thereby reducing a contact resistance between the contact and the gate layer. Furthermore, the connection of the contact with the plurality of portions of the same gate layer may reduce an extending dimension of the gate layer while ensuring the electrical performance of the semiconductor device, thereby reducing a bulk resistance of the gate layer and improving the level of integration of the semiconductor device.

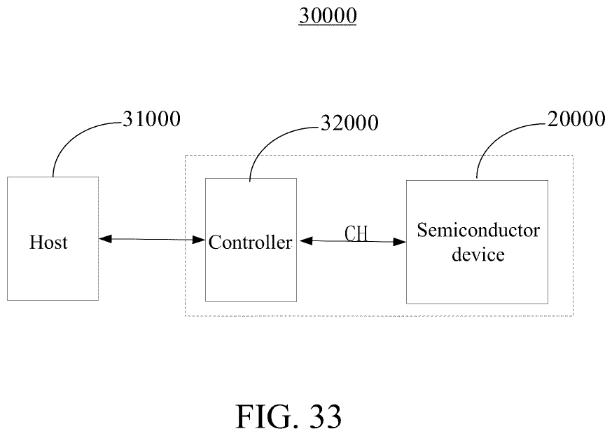

FIG. 33 is a schematic structural diagram of a memory system 30000, according to an implementation of the present disclosure.

As shown in FIG. 33, at least one implementation of yet another aspect of the present disclosure further provides a memory system 30000. The memory system 30000 may include a semiconductor device 20000 and a controller 32000. The semiconductor device 20000 may be the same as the semiconductor device as described in any implementation above, which is no longer repeated in the present disclosure. The semiconductor device 20000 may be a two-dimensional semiconductor device or a three-dimensional semiconductor device, or even a part of a two-dimensional semiconductor device or a part of a three-dimensional semiconductor device. An illustration will be made below by taking the three-dimensional semiconductor device as an example.

As an option, the three-dimensional semiconductor device may include at least one of a three-dimensional NAND memory and a three-dimensional NOR memory.

The memory system 30000 may include the semiconductor device 20000 and the controller 32000. The semiconductor device 20000 may be the same as the semiconductor device as described in any implementation above, which is no longer repeated in the present disclosure. The controller 32000 may control the semiconductor device 20000 through a channel CH, and the semiconductor device 20000 may perform operations based on control of the controller 32000 in response to a request from a host 31000. The semiconductor device 20000 may receive a command CMD and an address ADDR from the controller 32000 through the channel CH, and access a region selected from a memory cell array in response to the address. In other words, the semiconductor device 20000 may perform an internal operation corresponding to the command on the region selected by the address.

In some implementations, the three-dimensional memory system may be implemented as, for example, a Universal Flash Storage (UFS) device, a solid-state drive (SSD), a multi-media card of MMC, eMMC, RS-MMC and micro-MMC forms, a secure digital card of SD, mini-SD and micro-SD forms, a memory device of a Personal Computer Memory Card International Association (PCMCIA) card type, a memory device of a Peripheral Component Interconnection (PCI) type, a memory device of a PCI-Express (PCI-E) type, a Compact Flash (CF) card, a smart media card, or a memory stick, etc. The memory system provided by the present disclosure, as being provided with the semiconductor device provided by the present disclosure, has the same beneficial effects as the semiconductor device, which is no longer repeated here.

Although an example fabrication method and an example structure of the semiconductor device have been described here, it may be understood that one or more features may be omitted, replaced or added from a structure of the semiconductor device. Furthermore, the illustrated materials of various layers are merely examples.

The above descriptions are merely descriptions of examples implementations of the present disclosure and technical principles employed. One of ordinary skill understands that the protection scope of the present disclosure is not limited to the technical solutions formed by a selected combination of the above technical features and should also encompass other technical solutions formed by any combination of the above technical features or equivalent features thereof without departing from the technical conception at the same time. For example, technical solutions resulted from substitutions of the above-mentioned features by technical features of similar functions (but not limited to) disclosed in the present disclosure) still fall within the scope of the present disclosure.

What is claimed is:

1. A semiconductor device, comprising:
a stack structure comprising a plurality of gate layers stacked along a first direction; and
a plurality of contacts connected with the gate layers located at different stacking heights, respectively, wherein
the gate layer extends from a first region of the stack structure to a second region of the stack structure along a second direction, a portion of the gate layer located in the second region comprises two sub-gate layers disposed opposite to each other along a third direction, and the first direction, the second direction, and the third direction intersect each other;
the sub-gate layer comprises an extension extending along the second direction and a protrusion connected with the extension, with the protrusion of one of the sub-gate layers protruding toward the other sub-gate layer opposite thereto; and
the contact extends along the first direction and is connected with the extension and the protrusion of the gate layer.

2. The semiconductor device of claim 1, wherein
the protrusion is disposed opposite to the contact in the third direction; and
the contact is connected with the extension of the one of the sub-gate layers and connected with the protrusion of the other sub-gate layer.

3. The semiconductor device of claim 1, wherein
the extension and the protrusion of a same sub-gate layer are disposed around the contact; and
the contact is connected with the extension and the protrusion of the same sub-gate layer.

4. The semiconductor device of claim 1, wherein the protrusion of the one of the sub-gate layers is disposed as being staggered from the protrusion of the other sub-gate layer in the second direction.

5. The semiconductor device of claim 1, wherein the contact is disposed as being staggered from the protrusion in the second direction.

6. The semiconductor device of claim 1, wherein the contact is connected with at least one surface of the protrusion.

7. The semiconductor device of claim 1, wherein in a plane intersecting the first direction, a width of the extension is greater than or equal to a width of the protrusion.

8. The semiconductor device of claim 1, further comprising:
a gate line slit structure, wherein the gate line slit structure extends along the first direction and is connected with the plurality of gate layers stacked along the first direction.

9. The semiconductor device of claim 8, wherein
the gate line slit structure extends from the first region to the second region along the second direction, and a portion of the gate line slit structure located in the second region comprises a first portion and a second portion, wherein
the first portion extends along the second direction; and
the second portion extends along a direction intersecting the second direction.

10. The semiconductor device of claim 8, wherein
the gate line slit structure comprises a first gate line slit structure, a second gate line slit structure, and a third gate line slit structure located between the first gate line slit structure and the second gate line slit structure; and
the third gate line slit structure extends along a direction intersecting the second direction.

11. The semiconductor device of claim 9, wherein the extension is located between the first portion and the second portion.

12. The semiconductor device of claim 9, wherein
the gate line slit structure comprises a first gate line slit structure and a second gate line slit structure adjacent to each other in the third direction;
the second portion of the first gate line slit structure extends toward the second gate line slit structure;
the second portion of the second gate line slit structure extends toward the first gate line slit structure; and
the second portion of the first gate line slit structure and the second portion of the second gate line slit structure are connected with each other.

13. The semiconductor device of claim 9, wherein
the gate line slit structure comprises a first gate line slit structure and a second gate line slit structure adjacent to each other in the third direction;
the second portion of the first gate line slit structure extends toward the second gate line slit structure;
the second portion of the second gate line slit structure extends toward the first gate line slit structure; and
the second portion of the first gate line slit structure and the second portion of the second gate line slit structure are disposed as being staggered from each other in the second direction.

14. The semiconductor device of claim 8, wherein at least one surface of the gate line slit structure is a curved surface, and the curved surface comprises at least one of a concave surface and a convex surface.

15. The semiconductor device of claim 1, further comprising:
a first channel structure and a second channel structure, wherein
the first channel structure is located in the first region and extends through portions of the plurality of gate layers that are located in the first region along the first direction;
the second channel structure is located in the second region and at least extends through portions of the gate layers that are located in the second region along the first direction; and.
a plurality of the second channel structures are arranged at intervals in the protrusion along an extending direction of the protrusion.

16. The semiconductor device of claim 1, wherein
the contact comprises a first sub-portion and a second sub-portion connected with each other;
the first sub-portion extends along the first direction; and
the second sub-portion connects the gate layer and the first sub-portion at a stacking height where the gate layer corresponding to the contact is located.

17. A method of fabricating a semiconductor device, comprising:
forming a stack structure and forming a gate line slit and a contact hole in the stack structure, wherein the stack structure comprises a plurality of gate sacrificial layers stacked along a first direction;
removing a portion of the gate sacrificial layer via the gate line slit to form a sacrificial void; and
forming a gate layer in the sacrificial void and forming a contact in the contact hole, wherein
the gate layer extends along a second direction and comprises two sub-gate layers disposed opposite to each other along a third direction, and the first direction, the second direction, and the third direction intersect each other;
the sub-gate layer comprises an extension extending along the second direction and a protrusion connected with the extension, and the protrusion of one of the sub-gate layers protrudes toward the other sub-gate layer opposite thereto; and
the contact extends along the first direction and is connected with the extension and the protrusion of the gate layer.

18. The method of claim 17, wherein
the stack structure comprises a first region and a second region arranged along the second direction, and forming the gate line slit comprises:
forming first holes extending in the stack structure along the first direction, wherein a plurality of the first holes comprise a plurality of first region first holes located in the first region and a plurality of second region first holes located in the second region, a part of the plurality of second region first holes are arranged at intervals along the second direction, and the other part of the plurality of second region first holes are arranged at intervals along a direction intersecting the second direction; and
at least removing a portion of the stack structure that is located between adjacent ones of
the first holes to form the gate line slit; and
the method further comprises:.
forming a first channel hole and a second channel hole, wherein
the first channel hole and the second channel hole both extend in the stack structure along the first direction; and
the first channel hole and the second channel hole are formed in a process of forming the first hole.

19. The method of claim 17, wherein
removing the portion of the gate sacrificial layer via the gate line slit to form the sacrificial void comprises:
forming two sacrificial sub-voids disposed opposite to each other along the third direction, wherein
the sacrificial sub-void comprises a first void extending along the second direction and a second void communicated with the first void, with the second void of one of the sacrificial sub-voids protruding toward the other sacrificial sub-void opposite thereto; and
forming the sacrificial void further comprises:
forming the sacrificial void via the gate line slit and the contact hole, wherein
a width of the first void is greater than or equal to a width of the second void in a plane intersecting the first direction.

20. A memory system, comprising:
at least one semiconductor device, comprising:
a stack structure comprising a plurality of gate layers stacked along a first direction; and
a plurality of contacts connected with the gate layers located at different stacking heights, respectively, wherein
the gate layer extends from a first region of the stack structure to a second region of the stack structure along a second direction, a portion of the gate layer located in the second region comprises two sub-gate layers disposed opposite to each other along a third direction, and the first direction, the second direction, and the third direction intersect each other;
the sub-gate layer comprises an extension extending along the second direction and a protrusion connected with the extension, with the protrusion of one of the sub-gate layers protruding toward the other sub-gate layer opposite thereto;
the contact extends along the first direction and is connected with the extension and the protrusion of the gate layer; and
a controller coupled with the semiconductor device and configured to control the semiconductor device to store data.
